(19) United States
(12) Patent Application Publication
(10) Pub. No.: US 2007/0003787 A1
(43) Pub. Date: Jan. 4, 2007

(54) Organic light-emitting device and method of manufacturing the same

(76) Inventors: Tae-Woo Lee, Seoul (KR); Sang-Hoon Park, Seongnam-si (KR); Yu-Jin Kim, Suwon-si (KR); Jhun-Mo Son, Yongin-si (KR); Sang-Yeol Kim, Gwacheon-si (KR); Mu-Gyeom Kim, Hwaseong-si (KR); O-Hyun Kwon, Seoul (KR)

Correspondence Address: Robert E. Bushnell, Suite 300, 1522 K. Street, N.W., Washington, DC, 20005, US

(21) Appl. No.: 11/392,876

(22) Filed: Mar. 30, 2006

(30) Foreign Application Priority Data
Jun. 29, 2005 (KR) 10-2005-0057134

(51) Int. Cl. H01L 51/54; H05B 33/14

(52) U.S. Cl. 428/690; 428/917; 313/504; 313/506; 257/40; 257/E51.036; 427/66

(57) ABSTRACT

An organic light-emitting device includes a first electrode, a second electrode, and an organic layer interposed between the first electrode and the second electrode. The organic layer includes at least a light-emitting layer, wherein the light-emitting layer includes a plurality of compounds which have individually a light-emitting repeating unit and at least one of a hole-transporting repeating unit and an electron-transporting repeating unit and which are different in the molar ratio of the light-emitting repeating unit and at least one of the hole-transporting repeating unit and the electron-transporting repeating unit, and wherein the plurality of the compounds are stacked so that the molar ratio of the hole-transporting repeating unit may decrease and/or the molar ratio of the electron-transporting repeating unit may increase in the direction from the first electrode toward the second electrode. The hole transport capability of the light-emitting layer decreases in the direction from the first electrode toward the second electrode and the electron transport capability of the light-emitting layer decreases in the direction from the second electrode to the first electrode. Therefore, hole transport and electron transport are equilibrated, thereby ensuring high efficiency and long lifetime.

### CROSS-REFERENCE TO RELATED PATENT APPLICATION AND CLAIM OF PRIORITY

This application claims priority from Korean Patent Application No. 10-2005-0057134, filed on Jun. 29, 2005, in the Korean Intellectual Property Office, the disclosure of which is incorporated herein in its entirety by reference.

### BACKGROUND OF THE INVENTION

1. Field of the Invention

The present invention relates to an organic light-emitting device and a method of manufacturing the same. More particularly, the present invention relates to an organic light-emitting device including a light-emitting layer made of a plurality of compounds which are different in the molar ratio of a light-emitting repeating unit and at least one of a hole-transporting repeating unit and an electron-transporting repeating unit, wherein the plurality of the compounds are stacked so that the molar ratio of the hole-transporting repeating unit may decrease and/or the molar ratio of the electron-transporting repeating unit may increase in the direction from a first electrode toward a second electrode, and a method of manufacturing the same.

2. Description of the Related Art

Organic Light-Emitting Devices (OLEDs) are self-emission displays that emit light by recombination of electrons and holes in an organic layer made of a fluorescent or phosphorescent compound when a current is applied to the organic layer. The OLEDs have advantages such as lightweight, simple constitutional elements, easy fabrication process, superior image quality, and wide viewing angle. Furthermore, the OLEDs can accomplish perfect creation of dynamic images and high color purity. The OLEDs also have electrical properties suitable for portable electronic equipment such as low power consumption and low driving voltage.

The OLEDs can be classified into small molecular OLEDs (SMOLEDs) and polymer OLEDs (PLEDs) according to the molecular weight of a light-emitting layer material.

With respect to SMOLEDs, an organic layer including a light-emitting layer generally has a multi-layer structure further including a hole injection layer, a hole transport layer, an electron transport layer, and/or an electron injection layer, to efficiently enhance hole/electron transport. Meanwhile, an organic layer of PLEDs also includes a light-emitting layer. The organic layer may be formed by coating, such as spin casting, inkjet printing, nozzle printing or spray printing, of a solution obtained by dissolving any organic layer forming material in an appropriate organic solvent. Currently, such PLEDs and methods of manufacturing the same have been actively studied.

U.S. Pat. No. 6,603,150 to Liao et al., assigned to Eastman Kodak Company, discloses an organic light-emitting device including an interface layer between a hole transport layer and a light-emitting layer, wherein the energy bandgap of the interface layer is of the order of 3.0 eV or greater.

However, in conventional OLEDs, e.g., OLEDs including a first electrode, a hole injection layer, a light-emitting layer, an electron injection layer, and a second electrode, electrons are more accumulated on an interface of the light-emitting layer with the hole injection layer, and thus, an emission zone is mainly formed on the interface of the light-emitting layer with the hole injection layer. Therefore, the light-emitting layer is easily degraded at its interface with the hole injection layer, resulting in reduction in device efficiency and lifetime characteristics. Thus, it is necessary to solve the problems.

### SUMMARY OF THE INVENTION

The present invention provides an improved organic light-emitting device in which a light-emitting layer is designed so that hole transport capability decreases and/or electron transport capability increases in the direction from a first electrode toward a second electrode.

The present invention further provides an organic light-emitting device with better efficiency and lifetime characteristics, which includes a light-emitting layer made of a plurality of compounds, each having a light-emitting repeating unit and a hole-transporting repeating unit, wherein the plurality of the compounds are stacked so that the molar ratio of the hole-transporting repeating unit decreases in the direction from a first electrode toward a second electrode, and a method of manufacturing the same.

The present invention also provides an organic light-emitting device with better efficiency and lifetime characteristics, which includes a light-emitting layer made of a plurality of compounds, each having a light-emitting repeating unit and an electron-transporting repeating unit, wherein the plurality of the compounds are stacked so that the molar ratio of the electron-transporting repeating unit increases in the direction from a first electrode toward a second electrode, and a method of manufacturing the same.

The present invention also provides an organic light-emitting device satisfying all the requirements of the above-described two organic light-emitting devices, and a method of manufacturing the same.

According to a first aspect of the present invention, there is provided an organic light-emitting device including a first electrode; a second electrode; and an organic layer interposed between the first electrode and the second electrode. The organic layer includes at least a light-emitting layer. The light-emitting layer includes a plurality of compounds each of which has a light-emitting repeating unit and a hole-transporting repeating unit. The plurality of compounds are different in the molar ratio of the light-emitting repeating unit and the hole-transporting repeating unit, and the plurality of the compounds are stacked so that the molar ratio of the hole-transporting repeating unit decreases in the direction from the first electrode toward the second electrode.

According to a second aspect of the present invention, there is provided an organic light-emitting device including a first electrode; a second electrode; and an organic layer interposed between the first electrode and the second electrode. The organic layer includes at least a light-emitting layer. The light-emitting layer includes a plurality of compounds each of which has a light-emitting repeating unit and an electron-transporting repeating unit. The plurality of compounds are different in the molar ratio of the light-emitting repeating unit and the electron-transporting repeating unit, and the plurality of the compounds are stacked so that the molar ratio of the electron-transporting repeating unit increases in the direction from the first electrode toward the second electrode.

According to a third aspect of the present invention, there is provided an organic light-emitting device including a first electrode; a second electrode; and an organic layer interposed between the first electrode and the second electrode. The organic layer includes at least a light-emitting layer. The light-emitting layer includes a plurality of compounds each of which has a light-emitting repeating unit, a hole-transporting repeating unit, and an electron-transporting repeating unit. The plurality of compounds are different in the molar ratio of the light-emitting repeating unit, the hole-transporting repeating unit, and the electron-transporting repeating unit, and the plurality of the compounds are stacked so that the molar ratio of the hole-transporting repeating unit decreases and the molar ratio of the electron-transporting repeating unit increases, in the direction from the first electrode toward the second electrode.

According to a fourth aspect of the present invention, there is provided a method of manufacturing an organic light-emitting device, the method including: preparing a substrate including a first electrode; forming an organic layer on the first electrode; and forming a second electrode on the organic layer, wherein the organic layer includes a light-emitting layer made of a plurality of compounds, each of which includes a light-emitting repeating unit and a hole-transporting repeating unit, and the plurality of the compounds are stacked so that the molar ratio of the hole-transporting repeating unit decreases in the direction from the first electrode toward the second electrode.

According to a fifth aspect of the present invention, there is provided a method of manufacturing an organic light-emitting device, the method including: preparing a substrate including a first electrode; forming an organic layer on the first electrode; and forming a second electrode on the organic layer, wherein the organic layer includes a light-emitting layer made of a plurality of compounds, each of which includes a light-emitting repeating unit and an electron-transporting repeating unit, and the plurality of the compounds are stacked so that the molar ratio of the electron-transporting repeating unit increases in the direction from the first electrode toward the second electrode.

According to a sixth aspect of the present invention, there is provided a method of manufacturing an organic light-emitting device, the method including: preparing a substrate including a first electrode; forming an organic layer on the first electrode; and forming a second electrode on the organic layer, wherein the organic layer includes a light-emitting layer made of a plurality of compounds, each of which includes a light-emitting repeating unit, a hole-transporting repeating unit, and an electron-transporting repeating unit, and the plurality of the compounds are stacked so that the molar ratio of the hole-transporting repeating unit decreases and the molar ratio of the electron-transporting repeating unit increases, in the direction from the first electrode toward the second electrode.

In an organic light-emitting device of the present invention, a plurality of compounds constituting a light-emitting layer are stacked so that the molar ratio of a hole-transporting repeating unit decreases and/or the molar ratio of an electron-transporting repeating unit increases in the direction from a first electrode toward a second electrode. Therefore, hole transport and electron transport are balanced, thereby ensuring high efficiency and long lifetime.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIG. 1 is a schematic sectional view illustrating an organic light-emitting device according to an embodiment of the present invention;

FIG. 2 is a schematic sectional view illustrating an organic light-emitting device according to another embodiment of the present invention;

FIG. 3 is a graph illustrating efficiency characteristics of an organic light-emitting device according to the present invention; and

FIG. 4 is a graph illustrating lifetime characteristics of an organic light-emitting device according to the present invention.

### DETAILED DESCRIPTION OF THE INVENTION

Hereinafter, the present invention will be described more fully with reference to the accompanying drawings, in which exemplary embodiments of the invention are shown.

According to a first aspect of the present invention, there is provided an organic light-emitting device including a first electrode; a second electrode; and an organic layer interposed between the first electrode and the second electrode. The organic layer includes at least a light-emitting layer. The light-emitting layer includes a plurality of compounds each of which has a light-emitting repeating unit and a hole-transporting repeating unit. The plurality of compounds are different in the molar ratio of the light-emitting repeating unit and the hole-transporting repeating unit, and the plurality of the compounds are stacked so that the molar ratio of the hole-transporting repeating unit decreases in the direction from the first electrode toward the second electrode.

According to a second aspect of the present invention, there is provided an organic light-emitting device including a first electrode; a second electrode; and an organic layer interposed between the first electrode and the second electrode. The organic layer includes at least a light-emitting layer. The light-emitting layer includes a plurality of compounds each of which has a light-emitting repeating unit and an electron-transporting repeating unit. The plurality of compounds are different in the molar ratio of the light-emitting repeating unit and the electron-transporting repeating unit, and the plurality of the compounds are stacked so that the molar ratio of the electron-transporting repeating unit increases in the direction from the first electrode toward the second electrode.

According to a third aspect of the present invention, there is provided an organic light-emitting device including a first electrode; a second electrode; and an organic layer interposed between the first electrode and the second electrode. The organic layer includes at least a light-emitting layer. The light-emitting layer includes a plurality of compounds each of which has a light-emitting repeating unit, a hole-transporting repeating unit, and an electron-transporting repeating unit. The plurality of compounds are different in the molar ratio of the light-emitting repeating unit, the hole-transporting repeating unit, and the electron-transporting repeating unit, and the plurality of the compounds are stacked so that the molar ratio of the hole-transporting repeating unit decreases and the molar ratio of the electron-transporting repeating unit increases, in the direction from the first electrode toward the second electrode.

A plurality of compounds constituting a light-emitting layer of an organic light-emitting device according to the present invention are copolymers of a light-emitting repeating unit and a hole-transporting repeating unit, copolymers of a light-emitting repeating unit and an electron-transporting repeating unit, or terpolymers of a light-emitting repeating unit, a hole-transporting repeating unit, and an electron-transporting repeating unit. The plurality of the compounds have different the molar ratios of the light-emitting repeating unit and the hole-transporting repeating unit, the different molar ratios of the light-emitting repeating unit and the electron-transporting repeating unit, or the different molar ratios of the light-emitting repeating unit, the hole-transporting repeating unit, and the electron-transporting repeating unit. The plurality of the compounds are stacked so that the molar ratio of the hole-transporting repeating unit decreases and/or the molar ratio of the electron-transporting repeating unit increases, in the direction from a first electrode toward a second electrode. As used herein, the term “first electrode” refers to an electrode for supplying holes, and the term “second electrode” refers to an electrode for supplying electrons. The term “hole-transporting repeating unit” refers to a unit having better hole transport capability than electron transport capability, and the term “electron-transporting repeating unit” refers to a unit having better electron transport capability than hole transport capability. Thus, in the light-emitting layer, hole transport capability decreases in the direction from the first electrode toward the second electrode, electron transport capability decreases in the direction from the second electrode to the first electrode, and hole and electron transport occurs gradually. Therefore, the concentration of holes on an upper portion of the light-emitting layer or the concentration of electrons on a lower portion of the light-emitting layer does not occur, resulting in an organic light-emitting device with better brightness and lifetime.

According to an embodiment of the organic light-emitting device of the first aspect of the present invention, the light-emitting layer includes a plurality of compounds represented by Formula 1 below which are different in x, the plurality of the compounds being stacked so that x decreases in the direction from the first electrode toward the second electrode:

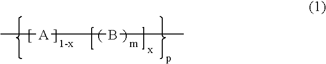

wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

B is a hole-transporting repeating unit selected from the group consisting of a substituted or unsubstituted arylene group of C₆-C₃₀, a substituted or unsubstituted heteroarylene group of C₂-C₃₀, a group represented by 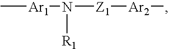
a group represented by 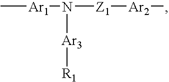
a group represented by 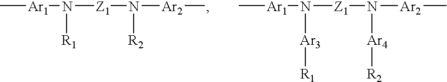
and a group represented by where Z₁ is a bond; an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, and R₁ and R₂ are an alkyl group of C₁-C₃₀ which is unsubstituted or substituted by at least one selected from the group consisting of a hydroxyl group, a cyano group, and a halogen atom; an alkoxy group of C₁-C₃₀ which is unsubstituted or substituted by at least one selected from the group consisting of a hydroxyl group, a cyano group, and a halogen atom; an aryl group of C₆-C₃₀ which is unsubstituted or substituted by at least one selected from the group consisting of a hydroxyl group, a cyano group, and a halogen atom; and a heteroaryl group of C₂-C₃₀ which is unsubstituted or substituted by at least one selected from the group consisting of a hydroxyl group, a cyano group, and a halogen atom;

m is 1 or 2;

x is a real number of 0.01 to 0.99; and

p is the degree of polymerization and a real number of 10 to 2,000.

The repeating units A and B can be arranged in any sequence provided that the molar ratio of 1-x and x is satisfied.

According to an embodiment of the organic light-emitting device of the second aspect of the present invention, the light-emitting layer includes a plurality of compounds represented by Formula 2 below which are different in y, the plurality of the compounds being stacked so that y increases in the direction from the first electrode toward the second electrode:

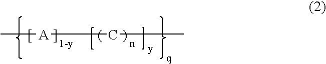

wherein A is a light-emitting repeating unit selected from the group consisting 11 of a substituted or unsubstituted arylene group of C₆-C₃₀, a substituted or unsubstituted vinylenearylene group of C₆-C₃₀, and a substituted or unsubstituted heteroarylene group of C₂-C₃₀;

C is an electron-transporting repeating unit selected from the group consisting of a substituted or unsubstituted arylene group of C₆-C₃₀ and a substituted or unsubstituted heteroarylene group of C₂-C₃₀;

n is 1 or 2;

y is a real number of 0.01 to 0.99; and

q is the degree of polymerization and a real number of 10 to 2,000.

The repeating units A and C can be arranged in any sequence provided that the molar ratio of 1-y and y is satisfied.

According to an embodiment of the organic light-emitting device of the third aspect of the present invention, the light-emitting layer includes a plurality of compounds represented by Formula 3 below which are different in x and y, the plurality of the compounds being stacked so that x decreases and y increases, in the direction from the first electrode toward the second electrode:

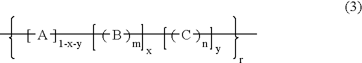

wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

B is a hole-transporting repeating unit selected from the group consisting of a substituted or unsubstituted arylene group of C₆-C₃₀, a substituted or unsubstituted heteroarylene group of C₂-C₃₀, a group represented by 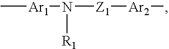
a group represented by 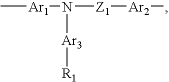
a group represented by 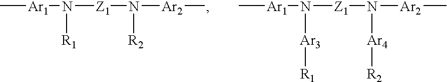
and a group represented by where Z₁ is a bond; an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, and R₁ and R₂ are an alkyl group of C₁-C₃₀ which is unsubstituted or substituted by at least one selected from the group consisting of a hydroxyl group, a cyano group, and a halogen atom; an alkoxy group of C₁-C₃₀ which is unsubstituted or substituted by at least one selected from the group consisting of a hydroxyl group, a cyano group, and a halogen atom; an aryl group of C₆-C₃₀ which is unsubstituted or substituted by at least one selected from the group consisting of a hydroxyl group, a cyano group, and a halogen atom; or a heteroaryl group of C₂-C₃₀ which is unsubstituted or substituted by at least one selected from the group consisting of a hydroxyl group, a cyano group, and a halogen atom;

C is an electron-transporting repeating unit selected from the group consisting of a substituted or unsubstituted arylene group of C₆-C₃₀ and a substituted or unsubstituted heteroarylene group of C₂-C₃₀;

m and n are each independently 1 or 2;

x and y are each independently a real number of 0.01 to 0.99; and

r is the degree of polymerization and a real number of 10 to 2,000.

The repeating units A, B, and C can be arranged in any sequence provided that the molar ratio of 1-x-y, x and y is satisfied.

In the above-described embodiments of the present invention, the light-emitting repeating unit represented by A, the hole-transporting repeating unit represented by B, and the electron-transporting repeating unit represented by C may be each independently substituted by at least one selected from the group consisting of a hydroxyl group; a cyano group; a halogen atom; an alkyl group of C₁-C₃₀ which is unsubstituted or substituted by a hydroxyl group, a cyano group, or a halogen atom; a cycloalkyl group of C₃-C₃₀ which is unsubstituted or substituted by a hydroxyl group, a cyano group, or a halogen atom; an alkoxy group of C₁-C₃₀ which is unsubstituted or substituted by a hydroxyl group, a cyano group, or a halogen atom; an aryl group of C₆-C₃₀ which is unsubstituted or substituted by a hydroxyl group, a cyano group, or a halogen atom; an arylalkyl group of C₆-C₃₀ which is unsubstituted or substituted by a hydroxyl group, a cyano group, or a halogen atom; a heteroaryl group of C₂-C₃₀ which is unsubstituted or substituted by a hydroxyl group, a cyano group, or a halogen atom; a heterocyclic group of C₂-C₃₀ which is unsubstituted or substituted by a hydroxyl group, a cyano group, or a halogen atom; and a group represented by —N(R′)(R″) where R′ and R″ are each independently selected from the group consisting of hydrogen, an alkyl group of C₁-C₃₀, an aryl group of C₆-C₃₀, and a heteroaryl group of C₂-C₃₀, but are not limited to the above-illustrated examples.

More specifically, the light-emitting repeating unit represented by A may be selected from the group consisting of 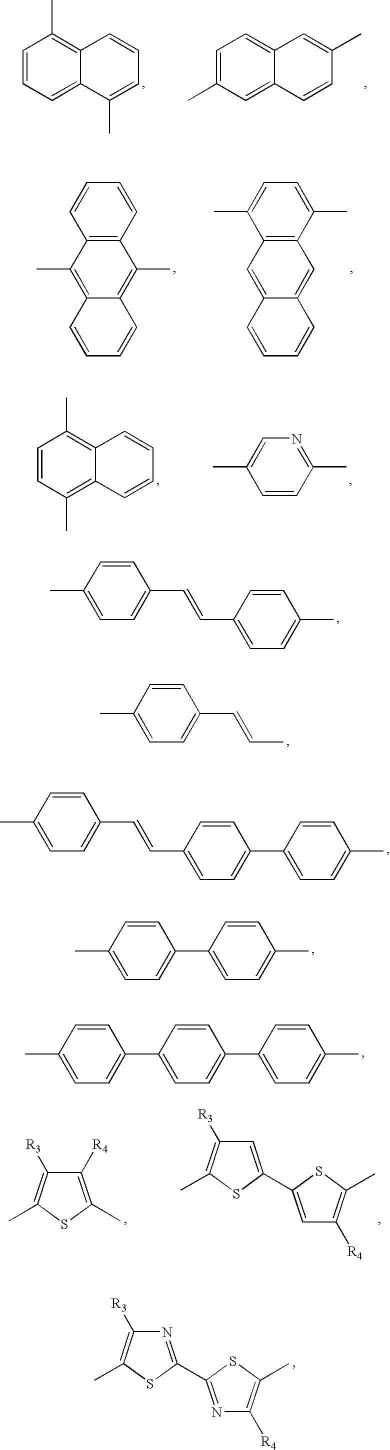 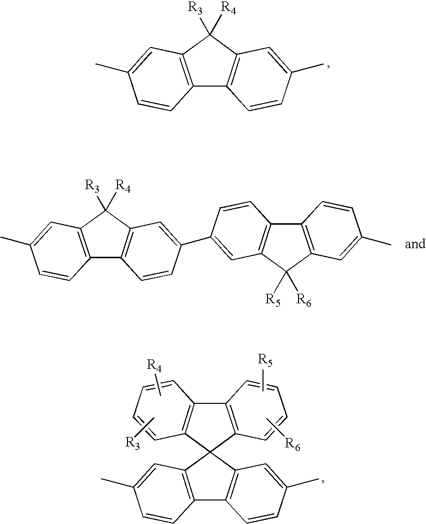
but is not limited to the above-illustrated examples. R₃, R₄, R₅ and R₆ are each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

Preferably, the light-emitting repeating unit represented by A is 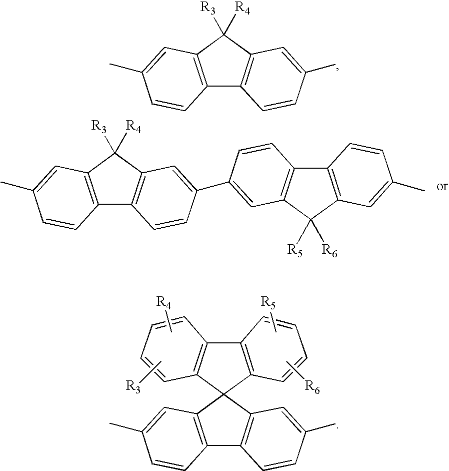
R₃, R₄, R₅ and R₆ are each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀. The reason the light-emitting repeating unit having a fluorene structure as described above is particularly preferable is that the fluorene structure has better fluorescence characteristics than other aromatic structures, and various solubilizing substituents including an alkyl group can be easily introduced into the positions 9 and 9′ of the fluorene structure, thereby ensuring excellent chemical flexibility.

The hole-transporting repeating unit represented by B may be selected from the group consisting of 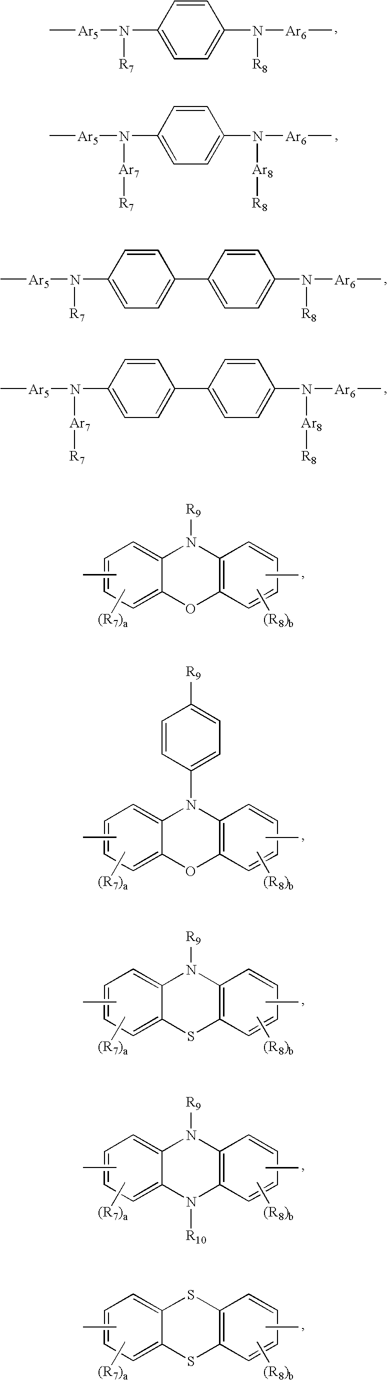 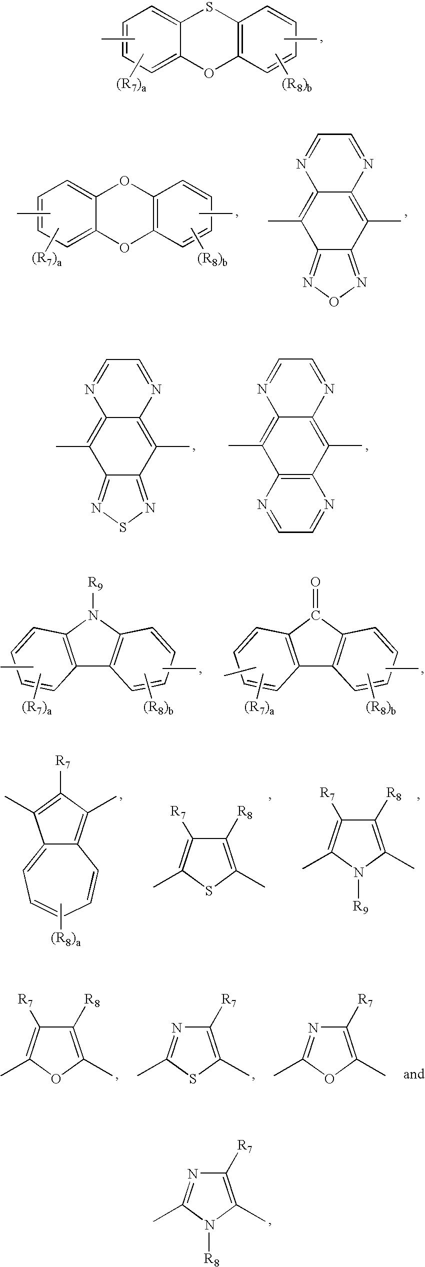
but is not limited to the above-illustrated examples. Ar₅, Ar₆, Ar₇ and Ar₈ are each independently an arylene group of C₆-C₃₀ or a heteroarylene group of C₅-C₃₀; R₇, R₈, R₉ and R₁₀ are each independently hydrogen, an alkyl group of C₁-C₁₂, an alkoxy group of C₁-C₁₂, an aryl group of C₆-C₃₀, or a heteroaryl group of C₆-C₃₀; and a and b are each independently 1, 2, 3, 4 or 5.

Preferably, the hole-transporting repeating unit represented by B is 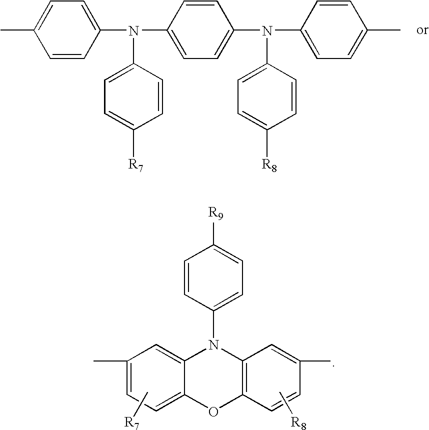
R₇, R₈ and R₉ are hydrogen, an alkyl group of C₁-C₁₂, an alkoxy group of C₁-C₁₂, an aryl group of C₆-C₃₀, or a heteroaryl group of C₆-C₃₀.

The electron-transporting repeating unit represented by C may be selected from the group consisting of 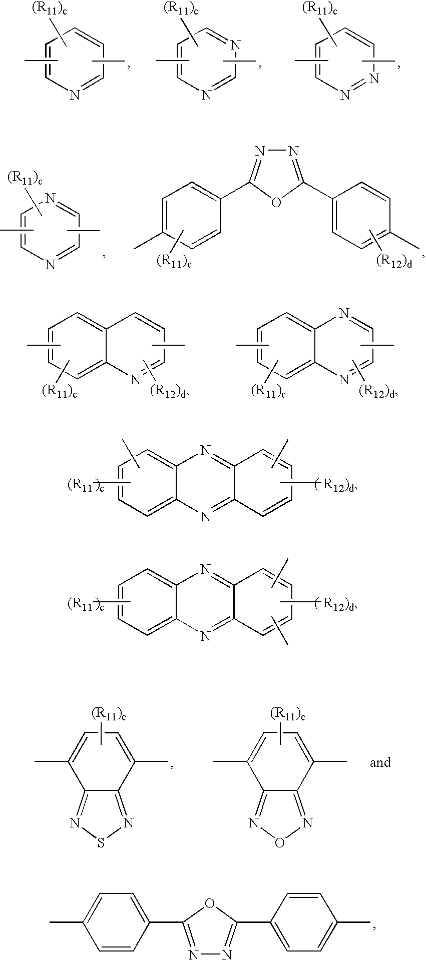
but is not limited to the above-illustrated examples. R₁₁, and R₁₂ are each independently hydrogen, an alkyl group of C₁-C₁₂, an alkoxy group of C₁-C₁₂, an aryl group of C₆-C₃₀, or a heteroaryl group of C₆-C₃₀; and c and d are each independently 1, 2, 3 or 4.

Preferably, the electron-transporting repeating unit represented by C is 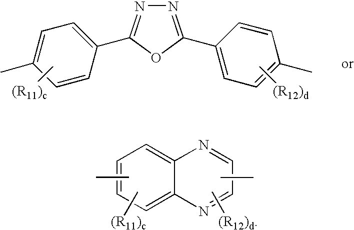
R₁₁ and R₁₂ are hydrogen, an alkyl group of C₁-C₁₂, an alkoxy group of C₁-C₁₂, an aryl group of C₆-C₃₀, or a heteroaryl group of C₆-C₃₀; and c and d are each independently 1, 2, 3, or 4.

In Formulae 1 and 3, m may be 1 or 2. In particular, when m is 2, the compounds represented by Formulae 1 and 3 may have the same or different types of B. Similarly, in Formulae 2 and 3, n may be 1 or 2. In particular, when n is 2, the compounds represented by Formulae 2 and 3 may have the same or different types of —C—.

In Formula 1, x is a parameter used for representing the molar ratio of the light-emitting repeating unit represented by A and the hole-transporting repeating unit represented by B. That is, the molar ratio of the light-emitting repeating unit represented by A and the hole-transporting repeating unit represented by B is 1-x to x. x is a real number of 0.01 to 0.99, and preferably, a real number of 0.1 to 0.9, but can be selected diversely.

In Formula 2, y is a parameter used for representing the molar ratio of the light-emitting repeating unit represented by A and the electron-transporting repeating unit represented by C. That is, the molar ratio of the light-emitting repeating unit represented by A and the electron-transporting repeating unit represented by C is 1-y to y. y is a real number of 0.01 to 0.99, and preferably, a real number of 0.1 to 0.9, but can be selected diversely.

In Formula 3, x and y are as described above.

In Formulae 1 through 3, p, q and r are the degree of polymerization, and each independently a real number of 10 to 2,000, and preferably, a real number of 50 to 200. If p, q or r is less than 10, it may be difficult to obtain a compound with satisfactory emission efficiency and hole transport capability and/or electron transport capability. On the other hand, if p, q or r exceeds 2,000, a common coating method may not be used.

According to an exemplary embodiment of the organic light-emitting device of the first aspect of the present invention, the light-emitting layer includes a compound represented by Formula 1a below and a compound represented by Formula 1b below, wherein x₁ of the compound of Formula 1a and x₂ of the compound of Formula 1b satisfy the requirement of x₁>x₂, and the compound of Formula 1a and the compound of Formula 1b are sequentially stacked from the first electrode:

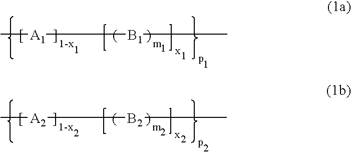

wherein A₁ and A₂ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

B₁ and B₂ are each independently a hole-transporting repeating unit selected from the group consisting of a substituted or unsubstituted arylene group of C₆-C₃₀, a substituted or unsubstituted heteroarylene group of C₂-C₃₀, a group represented by 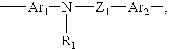
a group represented by 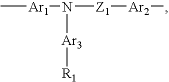
a group represented by 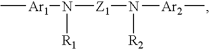
and a group represented by 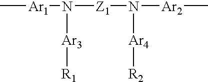
where Z₁ is a bond; an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, and R₁ and R₂ are an alkyl group of C₁-C₃₀ which is unsubstituted or substituted by at least one selected from the group consisting of a hydroxyl group, a cyano group, and a halogen atom; an alkoxy group of C₁-C₃₀ which is unsubstituted or substituted by at least one selected from the group consisting of a hydroxyl group, a cyano group, and a halogen atom; an aryl group of C₆-C₃₀ which is unsubstituted or substituted by at least one selected from the group consisting of a hydroxyl group, a cyano group, and a halogen atom; or a heteroaryl group of C₂-C₃₀ which is unsubstituted or substituted by at least one selected from the group consisting of a hydroxyl group, a cyano group, and a halogen atom;

m₁ and m₂ are each independently 1 or 2;

x₁ and x₂ are each independently a real number of 0.01 to 0.99;

p₁ and P₂ are the degree of polymerization and each independently a real number of 10 to 2,000.

The detailed description of A and B of Formula 1 can be applied to A₁, A₂, B₁ and B₂. A₁ and A₂ may be the same or different, and B₁ and B₂ may be the same or different.

x₁ and x₂ can be each independently selected from a real number of 0.01 to 0.99 with proviso that x₁>x₂. For example, x₁ may be 0.5 and x₂ may be 0.1. However, the present invention is not limited to the above-illustrated example.

When A₁ and A₂ are the same, the light-emitting repeating unit represented by A₁ and the light-emitting repeating unit represented by A₂ may be 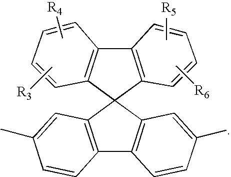
R₃, R₄, R₅ and R₆ may be each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

When B₁ and B₂ are the same, the hole-transporting repeating unit represented by B₁ and the hole-transporting repeating unit represented by B₂ may be 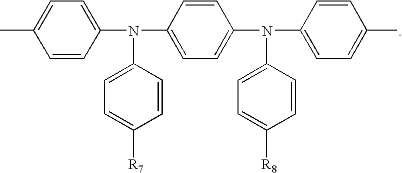
R₇ and R₈ may be hydrogen, an alkyl group of C₁-C₁₂, an alkoxy group of C₁-C₁₂, an aryl group of C₆-C₃₀, or a heteroaryl group of C₆₋₃₀.

When A₁ and A₂ are different, the light-emitting repeating unit represented by A₁ may be 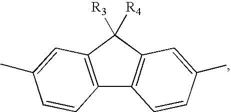
and the light-emitting repeating unit represented by A₂ may be 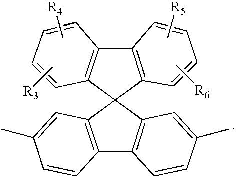
R₃, R₄, R₅ and R₆ may be each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

When —B₁— and —B₂— are different, the hole-transporting repeating unit represented by B₁ may be 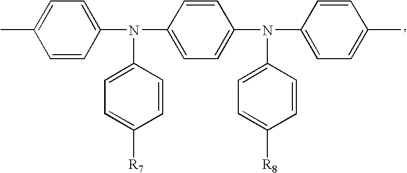
and the hole-transporting repeating unit represented by B₂ may be 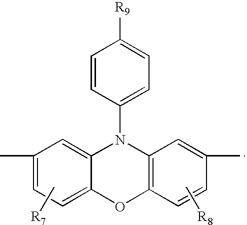
R₇ and R₈ may be hydrogen, an alkyl group of C₁-C₁₂, an alkoxy group of C₁-C₁₂, an aryl group of C₆-C₃₀, or a heteroaryl group of C₆-C₃₀.

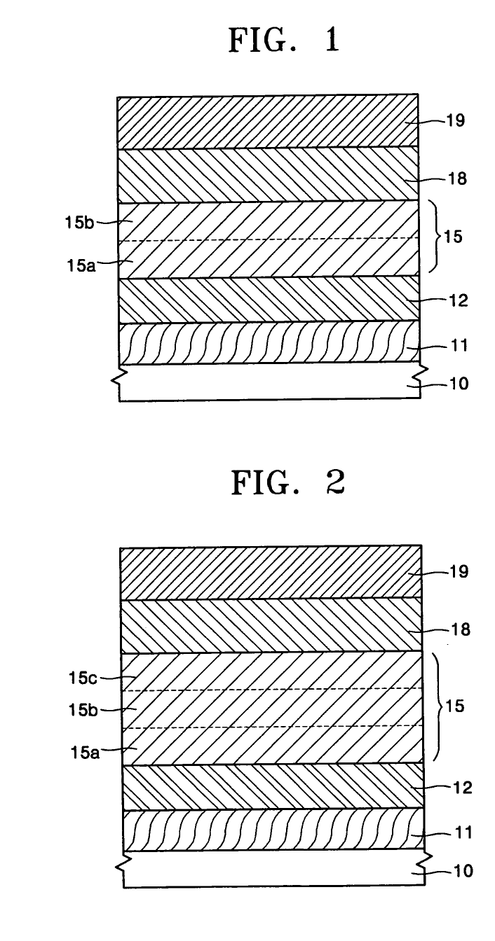

FIG. 1 is a schematic sectional view illustrating an organic light-emitting device according to the above-described embodiment. Referring to FIG. 1, a substrate 10, a first electrode 11, a hole injection layer 12, a light-emitting layer 15, an electron injection layer 18, and a second electrode 19 are sequentially stacked. The light-emitting layer 15 includes a 1a light-emitting layer 15a made of a compound of Formula 1a and a 1b light-emitting layer 15b made of a compound of Formula 1b.

Here, the “1a light-emitting layer” 15a and “1b light-emitting layer” 15b are the terms used to indicate the formation of the light-emitting layer 15 by sequential stacking of a compound of Formula 1a and a compound of Formula 1b. An interface between the 1a light-emitting layer 15a and the 1b light-emitting layer 15b is not distinct, unlike another interlayer interface (e.g., an interface between the electron injection layer 12 and the light-emitting layer 15). Thus, the interface between the 1a light-emitting layer 15a and the 1b light-emitting layer 15b is represented by a dotted line in FIG. 1. Actually, the light-emitting layer 15 can be observed as a single film.

In the light-emitting layer 15 of the organic light-emitting device shown in FIG. 1, x₁ of the 1a light-emitting layer 15a facing the first electrode 11 is greater than x₂ of the 1b light-emitting layer 15b facing the second electrode 19. That is, the molar ratio of the hole-transporting repeating unit of the 1a light-emitting layer 15a is greater than the molar ratio of the hole-transporting repeating unit of the 1b light-emitting layer 15b. In this regard, relationships given in Table 1 below are established:

TABLE 1

| Section | Relationship |
|---|---|
| Molar ratio of hole- | 1a light-emitting layer > 1b |
| transporting repeating unit | light-emitting layer |
| Molar ratio of light- | 1a light-emitting layer < 1b |
| emitting repeating unit | light-emitting layer |
| Hole mobility | 1a light-emitting layer > 1b |
| | light-emitting layer |
| Electron mobility | 1a light-emitting layer < 1b |
| | light-emitting layer |
| HOMO (High Occupied | 1a light-emitting layer < 1b |
| Molecular Orbital) level | light-emitting layer |
| LUMO (Low Unoccupied | 1a light-emitting layer > 1b |
| Molecular Orbital) level | light-emitting layer |

Therefore, hole transport and electron transport gradually occur in a light-emitting layer, and the uniform distribution of holes and electrons is accomplished, thereby ensuring better device efficiency and lifetime.

In more detail, the compound of Formula 1a may be a compound represented by Formula 4 or 5 below having the degree of polymerization of 50 to 500:

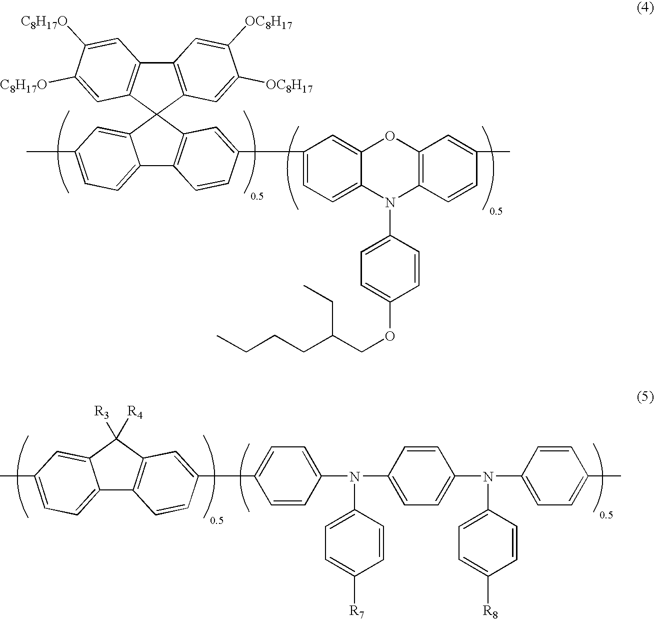

wherein R₃ and R₄ are each an alkyl group, in more detail, an ethylhexyl group or a hexyloctyl group, and R₇ and R₈ are each methyl, CF₃, methoxy (—OCH₃), OCF₃, n-butyl (—C₄H₉), —C₄F₉, sec-butyl, —COOEt, or —COOH. The compound of Formula 5 may be synthesized or commercially available from a chemical industry. For example, the compound of Formula 5 may be PFB (Dow Chemical).

The compound of Formula 1 b may be a compound represented by Formula 6 below:

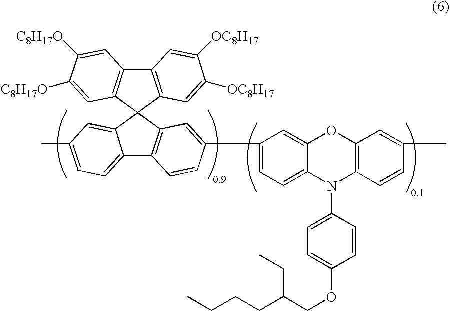

The degree of polymerization of the compound of Formula 6 may be 50 to 500.

According to another exemplary embodiment of the organic light-emitting device of the first aspect of the present invention, the light-emitting layer includes a compound represented by Formula 1a below, a compound represented by Formula 1b below, and a compound represented by Formula 1c below, wherein x₁ of the compound of Formula 1a, x₂ of the compound of Formula 1b, and x₃ of the compound of Formula 1c satisfy the requirement of x₁>x₂>x₃, and the compound of Formula 1a, the compound of Formula 1b, and the compound of Formula 1c are sequentially stacked from the first electrode:

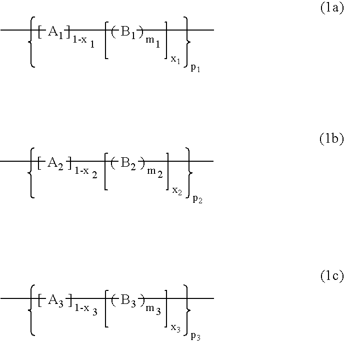

wherein A₁, A₂ and A₃ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

B₁, B₂ and B₃ are each independently a hole-transporting repeating unit selected from the group consisting of a substituted or unsubstituted arylene group of C₆-C₃₀, a substituted or unsubstituted heteroarylene group of C₂-C₃₀, a group represented by 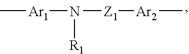
a group represented by 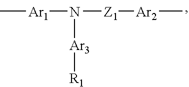
a group represented by 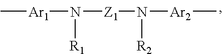
and a group represented by 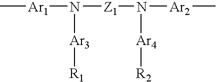
where Z₁ is a bond; an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, and R₁ and R₂ are an alkyl group of C₁-C₃₀ which is unsubstituted or substituted by at least one selected from the group consisting of a hydroxyl group, a cyano group, and a halogen atom; an alkoxy group of C₁-C₃₀ which is unsubstituted or substituted by at least one selected from the group consisting of a hydroxyl group, a cyano group, and a halogen atom; an aryl group of C₆-C₃₀ which is unsubstituted or substituted by at least one selected from the group consisting of a hydroxyl group, a cyano group, and a halogen atom; or a heteroaryl group of C₂-C₃₀ which is unsubstituted or substituted by at least one selected from the group consisting of a hydroxyl group, a cyano group, and a halogen atom;

m₁, m₂ and m₃ are each independently 1 or 2;

x₁, x₂ and x₃ are each independently a real number of 0.01 to 0.99;

p₁, p₂ and p₃ are the degree of polymerization and each independently a real number of 10 to 2,000.

The detailed description of A and B of Formula 1 can be applied to A₁, A₂, A₃, B₁ B₂ and B₃. A₁, A₂ and A₃ may be the same or different, and B₁, B₂ and B₃ may be the same or different.

x₁, x₂ and x₃ can be each independently selected from a real number of 0.01 to 0.99 with proviso that x₁>x₂>x₃. For example, x₁ may be 0.9, x₂ may be 0.5, and x₃ may be 0.1. However, the present invention is not limited to the above-illustrated example.

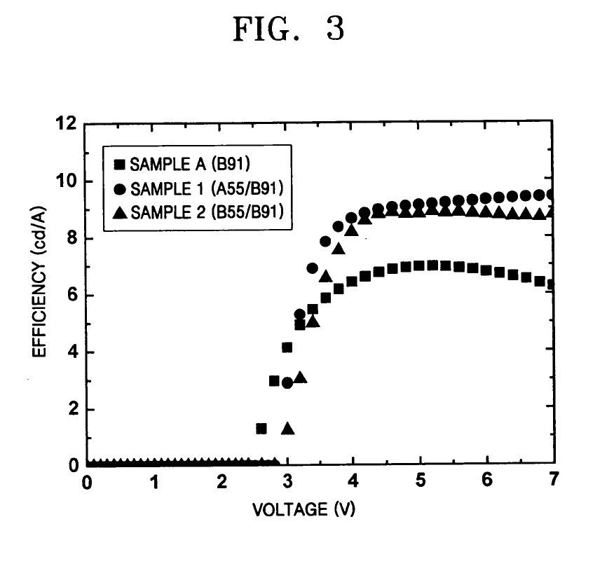

FIG. 2 is a schematic sectional view illustrating an organic light-emitting device according to the above-described embodiment. Referring to FIG. 2, a substrate 10, a first electrode 11, a hole injection layer 12, a light-emitting layer 15, an electron injection layer 18, and a second electrode 19 are sequentially stacked. The light-emitting layer 15 includes a 1a light-emitting layer 15a made of a compound of Formula 1a, a 1b light-emitting layer 15b made of a compound of Formula 1b, and a 1c light-emitting layer 15c made of a compound of Formula 1c.

Here, the “1a light-emitting layer” 15a, “1b light-emitting layer” 15b, and “1c light-emitting layer” 15c are the terms used to indicate the formation of the light-emitting layer 15 by sequential stacking of a compound of Formula 1a, a compound of Formula 1b, and a compound of Formula 1c. Interfaces among the 1a light-emitting layer 15a, the 1b light-emitting layer 15b, and the 1c light-emitting layer 15c are not distinct, unlike another interlayer interface. Thus, the interfaces among the 1a light-emitting layer 15a, the 1b light-emitting layer 15b, and the 1c light-emitting layer 15c are represented by dotted lines in FIG. 2. Actually, the light-emitting layer 15 can be observed as a single film.

In the light-emitting layer 15 of the organic light-emitting device shown in FIG. 2, x₁ of the 1a light-emitting layer 15a facing the first electrode 11 is greater than x₂ of the 1b light-emitting layer 15b, and x₂ is greater than x₃ of the 1c light-emitting layer 15c. In this regard, relationships given in Table 2 below are established:

TABLE 2

| Section | Relationship |
|---|---|
| Molar ratio of hole- | 1a light-emitting layer > 1b light- |
| transporting repeating unit | emitting layer > 1c light-emitting layer |
| Molar ratio of light- | 1a light-emitting layer < 1b light- |
| emitting repeating unit | emitting layer < 1c light-emitting layer |
| Hole mobility | 1a light-emitting layer > 1b light- |
| | emitting layer > 1c light-emitting layer |
| Electron mobility | 1a light-emitting layer < 1b light- |
| | emitting layer < 1c light-emitting layer |
| HOMO level | 1a light-emitting layer < 1b light- |
| | emitting layer < 1c light-emitting layer |
| LUMO level | 1a light-emitting layer > 1b light- |
| | emitting layer > 1c light-emitting layer |

Therefore, the efficiency and lifetime of the organic light-emitting device according to the present invention can be enhanced.

When the light-emitting layer 15 includes the 1a light-emitting layer 15a, the 1b light-emitting layer 15b, and the 1c light-emitting layer 15c, the light-emitting layer 15 may have a stacked structure in which compounds represented by Formulae 7, 4, and 6 below are sequentially stacked from the first electrode 11:

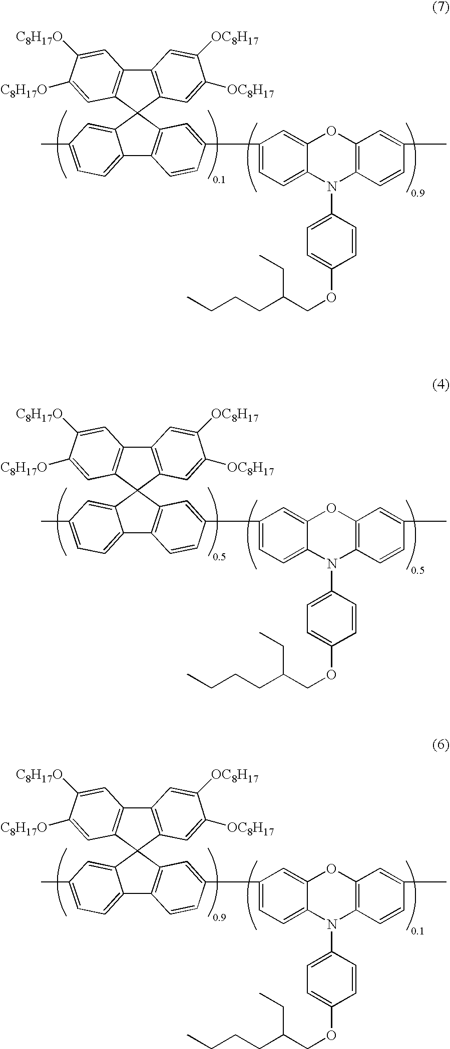

The compounds of Formulae 7, 4, and 6 may have each the degree of polymerization of 50 to 500.

With respect to a light-emitting layer made of a plurality of compounds each having a light-emitting repeating unit and a hole-transporting repeating unit, a light-emitting layer made of two compounds which are different in the molar ratio of a hole-transporting repeating unit and a light-emitting layer made of three compounds which are different in the molar ratio of a hole-transporting repeating unit have been illustrated. However, it should be understood by those of ordinary skill in the art that a light-emitting layer made of four or five compounds which are different in the molar ratio of a hole-transporting repeating unit is within the scope of the present invention.

According to an exemplary embodiment of the organic light-emitting device of the second aspect of the present invention, the light-emitting layer includes a compound represented by Formula 2a below and a compound represented by Formula 2b below, wherein y, of the compound of Formula 2a and y₂ of the compound of Formula 2b satisfy the requirement of y₁<y₂, and the compound of Formula 2a and the compound of Formula 2b are sequentially stacked from the first electrode:

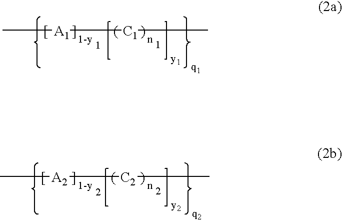

wherein A₁ and A₂ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

C₁ and C₂ are each independently an electron-transporting repeating unit selected from the group consisting of a substituted or unsubstituted arylene group of C₆-C₃₀ and a substituted or unsubstituted heteroarylene group of C₂-C₃₀;

n₁ and n₂ are each independently 1 or 2;

y₁ and y₂ are each independently a real number of 0.01 to 0.99;

q₁ and q₂ are the degree of polymerization, and each independently a real number of 10 to 2,000.

The detailed description of A and C of Formula 2 can be applied to A₁, A₂, C₁ and C₂. A₁ and A₂ may be the same or different, and C₁ and C₂ may the same or different.

y₁ and y₂ can be each independently selected from a real number of 0.01 to 0.99 with proviso that y₁<y₂. For example, y₁ may be 0.1 and y₂ may be 0.5. However, the present invention is not limited to the above-illustrated example.

According to this embodiment, referring to FIG. 1, a light-emitting layer 15 includes a 1a light-emitting layer 15a made of a compound of Formula 2a and a 1b light-emitting layer 15b made of a compound of Formula 2b. The molar ratio of the electron-transporting repeating unit of the 1a light-emitting layer 15a is smaller than that of the 1b light-emitting layer 15b. In this regard, relationships given in Table 3 below are established:

TABLE 3

| Section | Relationship |
|---|---|
| Molar ratio of electron- | 1a light-emitting layer < 1b light- |
| transporting repeating unit | emitting layer |
| Molar ratio of light-emitting | 1a light-emitting layer > 1b light- |
| repeating unit | emitting layer |
| Hole mobility | 1a light-emitting layer < 1b light- |
| | emitting layer |
| Electron mobility | 1a light-emitting layer > 1b light- |
| | emitting layer |
| HOMO level | 1a light-emitting layer > 1b light- |
| | emitting layer |
| LUMO level | 1a light-emitting layer < 1b light- |
| | emitting layer |

Therefore, hole transport and electron transport gradually occur in a light-emitting layer, and the uniform distribution of holes and electrons is accomplished, thereby ensuring better device efficiency and lifetime.

According to another exemplary embodiment of the organic light-emitting device of the second aspect of the present invention, the light-emitting layer includes a compound represented by Formula 2a below, a compound represented by Formula 2b below, and a compound represented by Formula 2c below, wherein y₁ of the compound of Formula 2a, y₂ of the compound of Formula 2b, and y₃ of the compound of Formula 2c satisfy the requirement of y₁<y₂<y₃, and the compound of Formula 2a, the compound of Formula 2b, and the compound of Formula 2c are sequentially stacked from the first electrode:

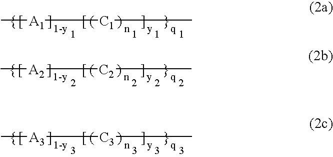

wherein A₁, A₂ and A₃ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₄-C₃₀;

—C₁—, —C₂ and —C₃— are each independently an electron-transporting repeating unit selected from the group consisting of a substituted or unsubstituted arylene group of C₆-C₃₀ and a substituted or unsubstituted heteroarylene group of C₂-C₃₀;

n₁, n₂ and n₃ are each independently 1 or 2;

y₁, y₂ and y₃ are each independently a real number of 0.01 to 0.99;

q₁, q₂ and q₃ are the degree of polymerization, and each independently a real number of 10 to 2,000.

The detailed description of A and C of Formula 2 can be applied to A₁, A₂, A₃, C₁ C₂ and C₃. A₁, A₂ and A₃ may be the same or different, and C₁, C₂ and C₃ may be the same or different.

y₁, y₂ and y₃ can be each independently selected from a real number of 0.01 to 0.99 with proviso that y₁<y₂<y₃. For example, y₁ may be 0.1, y₂ may be 0.5, and y₃ may be 0.9. However, the present invention is not limited to the above-illustrated example.

According to this embodiment, referring to FIG. 2, a light-emitting layer 15 includes a 1a light-emitting layer 15a made of a compound of Formula 2a, a 1b light-emitting layer 15b made of a compound of Formula 2b, and a 1c light-emitting layer 15c made of a compound of Formula 2c. In this regard, relationships given in Table 4 below are established.

TABLE 4

| Section | Relationship |
|---|---|
| Molar ratio of electron- | 1a light-emitting layer < 1b light- |
| transporting repeating unit | emitting layer < 1c light-emitting layer |
| Molar ratio of light- | 1a light-emitting layer > 1b light- |
| emitting repeating unit | emitting layer > 1c light-emitting layer |
| Hole mobility | 1a light-emitting layer < 1b light- |
| | emitting layer < 1c light-emitting layer |
| Electron mobility | 1a light-emitting layer > 1b light- |
| | emitting layer > 1c light-emitting layer |
| HOMO level | 1a light-emitting layer > 1b light- |
| | emitting layer > 1c light-emitting layer |
| LUMO level | 1a light-emitting layer < 1b light- |
| | emitting layer < 1c light-emitting layer |

Therefore, the efficiency and lifetime of the organic light-emitting device according to the present invention can be enhanced.

According to an exemplary embodiment of the organic light-emitting device of the third aspect of the present invention, the light-emitting layer includes a compound represented by Formula 3a below and a compound represented by Formula 3b below, wherein x₁ and y₁ of the compound of Formula 3a and x₂ and y₂ of the compound of Formula 3b satisfy the requirements of x₁>x₂ and y₁<y₂, and the compound of Formula 3a and the compound of Formula 3b are sequentially stacked from the first electrode:

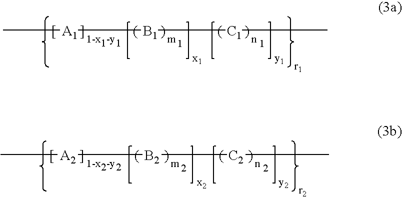

wherein A₁ and A₂ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

B₁ and B₂ are each independently a hole-transporting repeating unit selected from the group consisting of a substituted or unsubstituted arylene group of C₆-C₃₀, a substituted or unsubstituted heteroarylene group of C₂-C₃₀, a group represented by 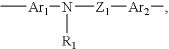
a group represented by 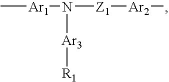
a group represented by 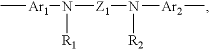
and a group represented by 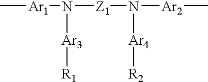
where Z₁ is a bond; an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, and R₁ and R₂ are an alkyl group of C₁-C₃₀ which is unsubstituted or substituted by at least one selected from the group consisting of a hydroxyl group, a cyano group, and a halogen atom; an alkoxy group of C₁-C₃₀ which is unsubstituted or substituted by at least one selected from the group consisting of a hydroxyl group, a cyano group, and a halogen atom; an aryl group of C₆-C₃₀ which is unsubstituted or substituted by at least one selected from the group consisting of a hydroxyl group, a cyano group, and a halogen atom; or a heteroaryl group of C₂-C₃₀ which is unsubstituted or substituted by at least one selected from the group consisting of a hydroxyl group, a cyano group, and a halogen atom;

C₁ and C₂ are each independently an electron-transporting repeating unit selected from the group consisting of a substituted or unsubstituted arylene group of C₆-C₃₀ and a substituted or unsubstituted heteroarylene group of C₂-C₃₀;

m₁, m₂, n₁ and n₂ are each independently 1 or 2;

x₁, x₂, y₁ and y₂ are each independently a real number of 0.01 to 0.99;

r₁ and r₂ are the degree of polymerization, and each independently a real number of 10 to 2,000.

According to another exemplary embodiment of the organic light-emitting device of the third aspect of the present invention, the light-emitting layer includes a compound represented by Formula 3a below, a compound represented by Formula 3b below, and the compound represented by Formula 3c below, wherein x₁ and y₁ of the compound of Formula 3a, x₂ and y₂ of the compound of Formula 3b, and x₃ and y₃ of the compound of Formula 3c satisfy the requirements of x₁>x₂>x₃ and y₁<y₂<y₃, and the compound of Formula 3a, the compound of Formula 3b, and the compound of Formula 3c are sequentially stacked from the first electrode:

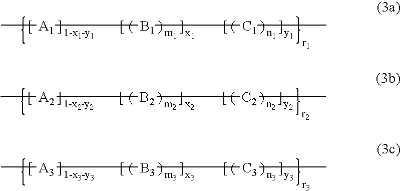

wherein A₁, A₂ and A₃ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;

B₁, B₂ and B₃ are each independently a hole-transporting repeating unit selected from the group consisting of a substituted or unsubstituted arylene group of C₆-C₃₀, a substituted or unsubstituted heteroarylene group of C₂-C₃₀, a group represented by 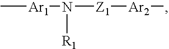
a group represented by 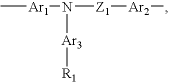
a group represented by 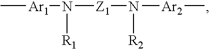
and a group represented by 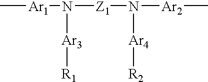
where Z₁ is a bond; an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, and R₁ and R₂ are an alkyl group of C₁-C₃₀ which is unsubstituted or substituted by at least one selected from the group consisting of a hydroxyl group, a cyano group, and a halogen atom; an alkoxy group of C₁-C₃₀ which is unsubstituted or substituted by at least one selected from the group consisting of a hydroxyl group, a cyano group, and a halogen atom; an aryl group of C₆-C₃₀ which is unsubstituted or substituted by at least one selected from the group consisting of a hydroxyl group, a cyano group, and a halogen atom; or a heteroaryl group of C₂-C₃₀ which is unsubstituted or substituted by at least one selected from the group consisting of a hydroxyl group, a cyano group, and a halogen atom;

C₁, C₂ and C₃ are each independently an electron-transporting repeating unit selected from the group consisting of a substituted or unsubstituted arylene group of C₆-C₃₀ and a substituted or unsubstituted heteroarylene group of C₂-C₃₀;

m₁, m₂, and m₃ are each independently 1 or 2;

n₁, n₂ and n₃ are each independently 1 or 2;

x₁, x₂, x₃ are each independently a real number of 0.01 to 0.99;

y₁, y₂ and y₃ are each independently a real number of 0.01 to 0.99;

r₁, r₂ and r₃ are the degree of polymerization, and each independently a real number of 10 to 2,000.

Here, the light-emitting layer made of a compound containing the light-emitting repeating unit, the hole-transporting repeating unit, and the electron-transporting repeating unit is as described above.

In an organic light-emitting device according to the present invention, a 9 light-emitting layer may have a thickness of 30 to 300 nm, preferably 50 to 100 nm, and more preferably 60 to 80 nm. If the thickness of the light-emitting layer is less than 30 nm, efficiency and lifetime may be lowered due to much leakage current. On the other hand, if it exceeds 300 nm, a driving voltage may increase greatly.

An organic layer of an organic light-emitting device of the present invention may further include, in addition to a light-emitting layer, at least one selected from the group consisting of a hole injection layer, a hole transport layer, a hole blocking layer, an electron blocking layer, an electron transport layer, and an electron injection layer. For example, an organic light-emitting device of the present invention may have a commonly known structure composed of first electrode/light-emitting layer/second electrode, first electrode/hole injection layer/light-emitting layer/second electrode, first electrode/hole transport layer/light-emitting layer/second electrode, first electrode/hole injection layer/light-emitting layer/electron injection layer/second electrode, etc., but is not limited thereto.

A hole injection layer material is not particularly limited but may be copper phthalocyanine (CuPc); Starburst amine such as TCTA, m-MTDATA, HI406 (Idemitsu Kosan Co., Ltd.); or a soluble conductive polymer such as Pani/DBSA (Polyaniline/Dodecylbenzenesulfonic acid), PEDOT/PSS (Poly(3,4-ethylenedioxythiophene)/Poly(4-styrenesulfonate)), Pani/CSA (Polyaniline/Camphor sulfonic acid), or PANI/PSS (Polyaniline)/Poly(4-styrenesulfonate)).

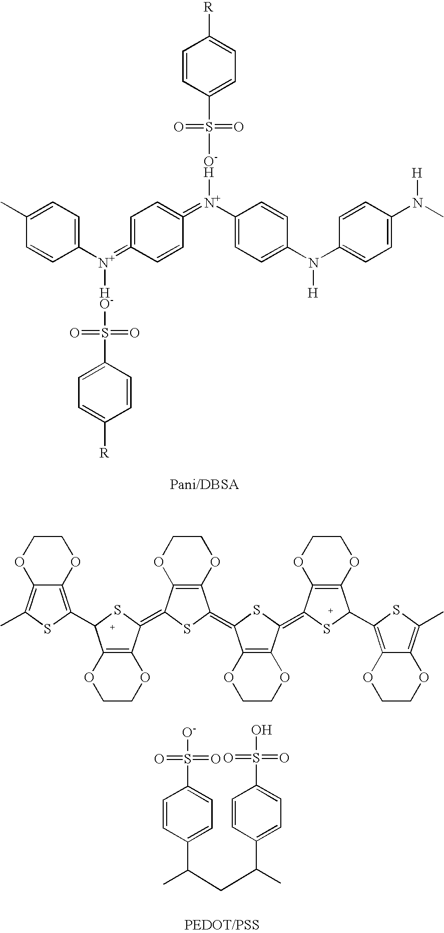

A hole injection layer may have a thickness of 5 to 100 nm, and preferably 10 to 70 nm. A hole injection layer with a thickness of 50 nm is more preferable. If the thickness of the hole injection layer is less than 5 nm, the hole injection layer may have poor hole injection characteristics due to its too thin thickness. On the other hand, if it exceeds 100 nm, light transmittance may be lowered.

A hole transport layer material is not particular limited but may be at least one hole transport material selected from the group consisting of a carbazole group—and/or an arylamine group-containing compound, a phthalocyanine compound, and a triphenylene derivative. In more detail, a hole transport layer may be made of at least one selected from 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (TPD), N,N′-di(naphthalene-1-yl)-N,N′-diphenylbenzidine (α-NPD), but is not limited to the above-illustrated examples.

The hole transport layer may have a thickness of 1 to 100 nm, and preferably 5 to 50 nm. A hole transport layer with a thickness of 30 nm or less is more preferable. If the thickness of the hole transport layer is less than 1 nm, the hole transport layer may have poor hole transport capability due to its too thin thickness. On the other hand, if it exceeds 100 nm, a driving voltage may increase.

An electron injection layer may be made of a material commonly used in the art. Preferably, an electron injection layer material is LiF, BaF₂, or MgF₂, but is not limited thereto.

The materials, thicknesses, etc. of a hole injection layer, a hole transport layer, a hole blocking layer, an electron transport layer, and an electron injection layer are known in the art, and thus a detailed description thereof will be omitted. For example, more detailed descriptions related thereto are disclosed in Korean Patent No. 0424090, Korean Patent Laid-Open Publication No. 2004-0081528 and No. 2004-0070561, the disclosures of which are incorporated herein in its entirety by reference.

For the fabrication of an organic light-emitting device of the present invention, there is no need to use a particular apparatus or method. Thus, an organic light-emitting device of the present invention can be manufactured according to a common method of manufacturing an organic light-emitting device using a light-emitting polymer.

Hereinafter, the present invention will be described more specifically with reference to the following examples. The following examples are for illustrative purposes and thus are not intended to limit the scope of the invention.

### EXAMPLES

### Synthesis Example 1

### Synthesis of Phenoxazine Monomer (Compound (C))

A compound (C), a phenoxazine monomer, was synthesized according to Reaction Scheme 1 below:

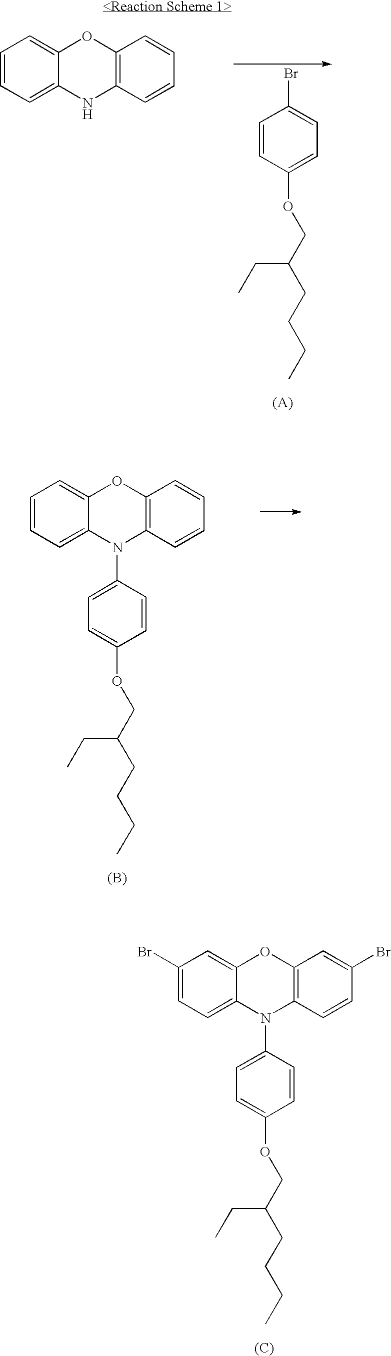

1) Synthesis of Compound (A)

50 g (0.29 mole) of 4-bromophenol was dissolved in 500 mL of acetone and 48.4 g (0.35 mole) of K₂CO₃ was added thereto. Then, 73.3 g (0.38 mole) of 1-bromooctane was added to the reaction mixture, and the resultant mixture was refluxed for 24 hours.

After the reaction terminated, the resultant solution was extracted with a mixed solvent of water and CHCl₃ (2:1, v/v) to remove K₂CO₃. The organic layer was dried over MgSO₄, concentrated, and purified by silica gel column chromatography using hexane as an eluent. The eluted solution was distilled under reduced pressure to remove unreacted 1-bromooctane, thereby yielding 80 g (yield: 96%) of a compound (A). The compound (A) was identified by ¹H-NMR.

2) Synthesis of Compound (B)

18 g (64 mmol) of the compound (A), 10 g (54 mmol) of phenoxazine, 7.4 g (77 mmol) of sodium tert-butoxide, 0.61 g (1.1 mmol) of Pd(dba)₂ [(Tris(dibenzylidine acetone)dipalladium(0))], and 0.22 g (1.1 mmol) of tri(tert-butyl)phosphine were dissolved in 250 mL of xylene, and the reaction mixture was incubated at 80° C. for 12 hours.

After the reaction terminated, the resultant solution was cooled to room temperature, quenched with 200 ml of distilled water, and extracted with a mixed solvent of xylene and water (1:1, v/v). The collected organic layer was dried over MgSO₄, concentrated, and purified by silica gel column chromatography using a mixed solvent of toluene and hexane (1:2, v/v) as an eluent. The eluted solution was concentrated and dried to give 18.5 g (yield: 88%) of a compound (B). The compound (B) was identified by ¹H-NMR.

3) Synthesis of Compound (C)

5 g (13 mmol) of the compound (B) was dissolved in 150 mL of CHCl₃. The reaction mixture was set to 0° C., and 2.1 eq. of bromine (based on the compound (B)) was gradually added thereto until no starting material was left by TLC analysis. Then, the reaction mixture was stirred for 10 minutes.

A small quantity of acetone was then added to the reaction mixture to quench bromine, and the resultant solution was extracted with a mixed solvent of water and CHCl₃ (2:1, v/v). The collected organic layer was dried over MgSO₄, concentrated, and re-precipitated in MeOH to give 6 g (yield: 85%) of a compound (C). The compound (C) was identified by ¹H-NMR.

¹H-NMR (300 MHz, CDCl₃): δ 0.91 (m, 6H), δ 1.45 (m, 8H), δ 1.82 (m, 1H), δ 3.89 (d, 2H), δ 5.82 (d, 2H), δ 6.5-7.5 (m, 8H)

### Synthesis Example 2

### Synthesis of 2,7-dibromo-2′,3′,6′,7′-dioctyloxy spirofluorene (Compound (F))

2,7-dibromo-2′,3′,6′,7′-dioctyloxy spirofluorene was synthesized according to Reaction Scheme 2 below:

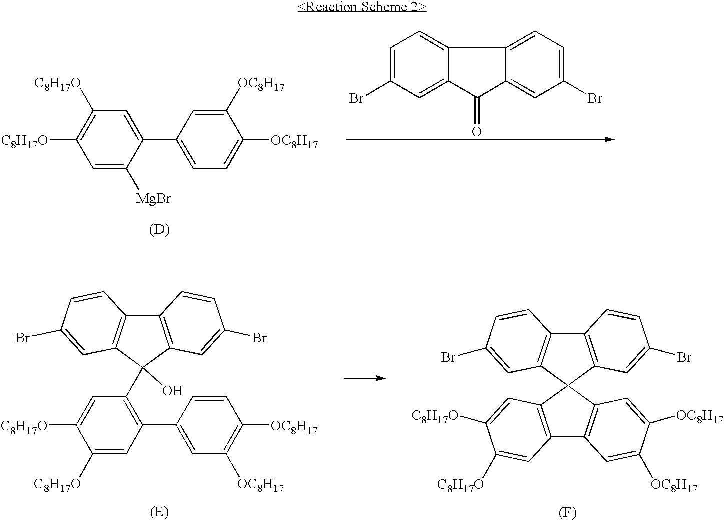

1) Synthesis of Compound (E)

3.36 g (10 mmol) of 2,7-dibromo-9-fluorenone was dissolved in 50 ml of ether and a solution of 8.45 g (11 mmol) of a compound (D) in 50 ml of ether was added thereto. The reaction mixture was then stirred under reflux overnight. After the reaction terminated, the resultant solution was cooled. The resultant yellow solid powder was filtered and washed with ether (x3). The product was added to ammonium chloride, and the resultant solution was stirred for 10 hours. The resultant precipitate was filtered and washed with water (x3). The crude product was recrystallized with ethanol to give a compound (E) (yield: 83%) as a yellow solid.

2) Synthesis of Compound (F)

5.0 g (5 mmol) of the compound (E) was added to 15 ml of CH₃COOH, and the reaction mixture was mildly stirred under reflux. 0.5 ml of HCl was added to the reaction solution followed by reflux for one hour. After the reaction terminated, the resultant solution was cooled to room temperature. The resultant solid powder was filtered and washed with water (x3). The crude product was recrystallized with ethanol to give 1.42 g (1.44 mmol) (yield: 29%) of a compound (F) as a white powder. The compound (F) was identified by ¹H-NMR.

¹H-NMR (300 MHz, CDCl₃): δ 7.60 (d, 2H), δ 7.43 (dd, 2H), δ 7.16 (d, 2H), δ 6.79 (s, 2H), δ 6.20 (s, 2H), δ 4.18 (m, 4H), δ 3.75 (m, 4H), δ 1.94 (m, 8H), δ 1.72 (m, 8H), δ 1.30 (m, 32H), δ 0.96 (m, 12H)

### Synthesis Example 3

### Synthesis of Poly(2′,3′,6′,7′-tetraoctyloxyspirofluorene) co-phenoxazine) [B55] of Formula 4 (spirofluorene Repeating Unit and phenoxazine Repeating Unit are 5:5 (Molar Ratio))

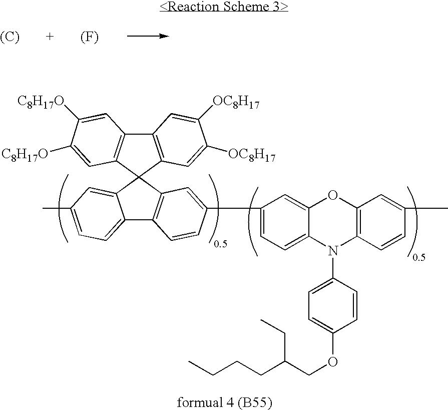

A Schlenk flask was several times subjected to evacuation and nitrogen reflux to completely remove moisture and then transferred into a glove box. Then, 880 mg (3.2 mmol) of Ni(COD)₂ and 500 mg (3.2 mmol) of bipyridal were added to the Schlenk flask and then several times subjected to evacuation and nitrogen reflux. Then, 10 ml of anhydrous DMF, 346 mg (3.2 mmol) of COD, and 10 ml of anhydrous toluene were added to the reaction mixture under nitrogen atmosphere, and the resultant mixture was stirred at 80° C. for 30 minutes. To the resultant solution, there was added a diluted solution obtained by diluting 43.6 mg (0.8 mmol) of the compound (C) obtained in Synthesis Example 1 and 790 g (0.8 mmol) of the compound (F) obtained in Synthesis Example 2, i.e., 2,7-dibromo-2′,3′,6′,7′-dioctyloxy spirofluorene in 10 ml of toluene. 10 ml of toluene was then added to the Schlenk flask with washing the inner wall of the flask and then the resultant mixture was stirred at 80° C. for 4 days. Then, 1 ml of bromopentafluorobenzene was added to the resultant solution, followed by stirring at 80° C. for about one day.

After the reaction terminated, the resultant solution was cooled to 60° C. and poured into a mixed solution of HCl, acetone, and methanol (1:1:2, by volume) to obtain a precipitate. The precipitate was dissolved in chloroform and poured into methanol to form a precipitate. The precipitate was subjected to a soxhlet extraction to give 620 mg (yield: 80%) of poly(2′,3′,6′,7′-tetraoctyloxy spirofluorene-co-phenoxazine) (spirofluorene repeating unit and phenoxazine repeating unit were 5:5 (molar ratio)). The polymer was analyzed by gel permeation chromatography (GPC). As a result, the weight average molecular weight (Mw) was 198,000 and the molecular weight distribution (MWD) was 2.07. The polymer was designated B55.

### Synthesis Example 4

### Synthesis of Poly(2′,3′,6′,7′-tetraoctyloxyspirofluorene)-co-phenoxazine of Formula 6 [B91] (spirofluorene Repeating Unit and phenoxazine Repeating Unit are 9:1 (Molar Ratio))

The titled compound was synthesized in the same manner as in Synthesis Example 3 except that 87 mg (0.16 mmol) of the compound (C) and 1.42 g (1.44 mmol) of the compound (F), i.e., 2,7-dibromo-2′,3′,6′,7′-dioctyloxy spirofluorene were used. The titled compound was designated B91.

Meanwhile, poly(9,9-dioctylfluorene-co-bis-N,N′-(4-butylphenyl)-bis-N,N′-phenyl-1,4-phenylenediamine) (PFB) (Dow Corning) was prepared. PFB was as represented by Formula 5, and had a number average molecular weight of about 100,000. PFB was designated A55.

### Example 1

### Manufacturing of Organic Light-Emitting Device Having the Structure of ITO/PEDOT:PSS/(A55/B91)/BaFg/Ca/Al

A corning 15 Ω/cm² (1,200 Å) ITO glass substrate was cut into pieces of 50 mm×50 mm×0.7 mm in size, followed by ultrasonic cleaning in deionized water and isopropyl alcohol (5 minutes for each) and then UV/ozone cleaning (30 minutes). Then, PEDOT:PSS (Baytron P AI4083, H. C. Starck, GmbH) was coated to a thickness of 50 nm on the ITO substrate at 2,000 rpm and heated at 200° C. for 10 minutes to form a hole injection layer.

Next, A55 was dissolved in 0.4 wt % xylene to prepare a mixture for forming an A55 layer and B91 was dissolved in 0.4 wt % xylene to prepare a mixture for forming a B91 layer. The mixtures were filtered with a 0.2 mm filter. The mixture for forming the A55 layer was spin-coated on the hole injection layer and thermally treated at 220° C. for 30 minutes to form the A55 layer with a thickness of about 28 nm. Then, the mixture for forming the B91 layer was coated on the A55 layer and thermally treated at 220° C. for 30 minutes to form the B91 layer to thereby complete a light-emitting layer with the thickness of about 45 nm. When the mixture for forming the B91 layer was coated on the A55 layer, an interface between the A55 layer and the B91 layer was not distinct due to intermixing by partial dissolution of the A55 layer in xylene. However, A55 and B91 were sequentially stacked without mixing.

An electron injection layer was then formed to a thickness of 3.1 nm on the light-emitting layer using BaF₂. A second electrode composed of a Ca layer (2.2 nm) and an Al layer (250 nm) was then formed on the electron injection layer to thereby complete an organic light-emitting device. The Ca layer and the Al layer were formed by sequential vacuum deposition of Ca and Al under a vacuum of 4×10⁻⁶ torr or less using a vacuum depositor. Upon the deposition, a film thickness and a film growth rate were adjusted using a crystal sensor. The organic light-emitting device was designated sample 1.

### Example 2

### Manufacturing of Organic Light-Emitting Device Having the Structure of ITO/PEDOT:PSS/(B55/B91)/BaF2/Ca/Al

An organic light-emitting device was manufactured in the same manner as in Example 1 except that B55 was used instead of A55 in the formation of a light-emitting layer. The organic light-emitting device was designated sample 2.

### Comparative Example

### Manufacturing of Organic Light-Emitting Device Having the Structure of ITO/PEDOT:PSS/B91/BaF2/Ca/Al

An organic light-emitting device was manufactured in the same manner as in Example 1 except that a B91 layer was formed on a hole injection layer without forming an A55 layer. The organic light-emitting device was designated sample A.

### Evaluation Example

### Evaluation of Efficiency and Lifetime Characteristics

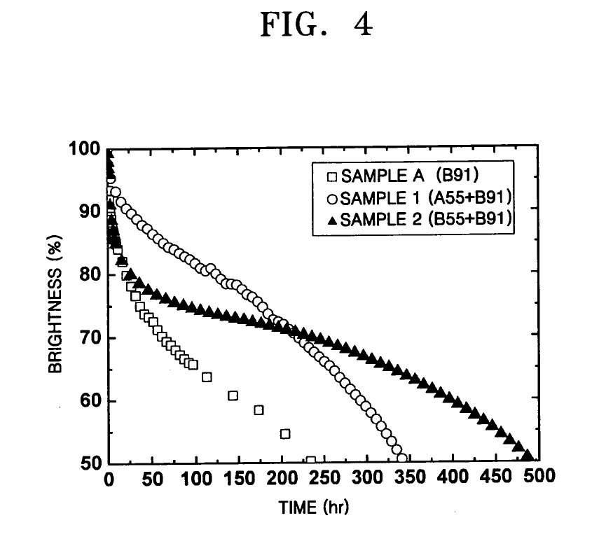

The efficiency and lifetime characteristics of the samples 1, 2, and A were evaluated and the results are shown in FIGS. 3 and 4. Here, a forward bias direct-current voltage was used as a driving voltage. The lifetime characteristics were evaluated by the time taken for reaching ½ of initial brightness.

As shown in FIG. 3, the samples 1 and 2 exhibited better efficiency than the sample A. In particular, at a driving voltage of 7V, the efficiency of the samples 1 and 2 was about 9 cd/A which was of the order of about 1.5 times greater than that (about 6 cd/A) of the sample A.

The evaluation results for the lifetime characteristics shown in FIG. 4 are summarized in Table 3 below:

TABLE 3

| Sample No. | Lifetime (hrs) at 800 cd/m² |
|---|---|
| A | 240 |
| 1 | 330 |
| 2 | 490 |

As presented in Table 3, the samples 1 and 2 according to the present invention exhibited better lifetime characteristics than the sample A.

In an organic light-emitting device of the present invention, when a light-emitting layer is made of a plurality of compounds each having a light-emitting repeating unit and a hole-transporting repeating unit, the plurality of the compounds are stacked so that the molar ratio of the hole-transporting repeating unit decreases in the direction from a first electrode toward a second electrode. When a light-emitting layer is made of a plurality of compounds each having a light-emitting repeating unit and an electron-transporting repeating unit, the plurality of the compounds are stacked so that the molar ratio of the electron-transporting repeating unit increases in the direction from a first electrode toward a second electrode. When a light-emitting layer is made of a plurality of compounds each having a light-emitting repeating unit, a hole-transporting repeating unit, and an electron-transporting repeating unit, the plurality of the compounds are stacked so that the molar ratio of the hole-transporting repeating unit decreases and the molar ratio of the electron-transporting repeating unit increases, in the direction from a first electrode toward a second electrode. Therefore, hole transport and electron transport are equilibrated, thereby ensuring high efficiency and long lifetime.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light-emitting device, comprising:
a first electrode;
a second electrode; and
an organic layer interposed between the first electrode and the second electrode, the organic layer comprising at least a light-emitting layer, the light-emitting layer having at least one characteristic selected from the group consisting of a decrease of a hole transport capability and an increase of an electron transport capability in the direction from the first electrode toward the second electrode.

2. The organic light-emitting device of claim 1, wherein the light-emitting layer comprises a plurality of compounds, each compound having a light-emitting repeating unit and a hole-transporting repeating unit, said plurality of compounds being different in the molar ratio of the light-emitting repeating unit and the hole-transporting repeating unit.

3. The organic light-emitting device of claim 1, wherein the light-emitting layer comprises a plurality of compounds, each compound having a light-emitting repeating unit and a electron-transporting repeating unit, said plurality of compounds being different in the molar ratio of the light-emitting repeating unit and the electron-transporting repeating unit.

4. The organic light-emitting device of claim 1, wherein the light-emitting layer comprises a plurality of compounds, each compound having a light-emitting repeating unit, a hole-transporting repeating unit, and a electron-transporting repeating unit, said plurality of compounds being different in the molar ratio of the light-emitting repeating unit, the hole-transporting repeating unit, and the electron-transporting repeating unit.

5. An organic light-emitting device, comprising:
a first electrode;
a second electrode; and
an organic layer interposed between the first electrode and the second electrode, the organic layer comprising at least a light-emitting layer, the light-emitting layer comprising a plurality of compounds, each of which has a light-emitting repeating unit and a hole-transporting repeating unit, said plurality of compounds being different in the molar ratio of the light-emitting repeating unit and the hole-transporting repeating unit, the molar ratio of the hole-transporting repeating unit in the light-emitting layer decreasing in the direction from the first electrode toward the second electrode.

6. The organic light-emitting device of claim 5, wherein the plurality of compounds are represented by Formula 1, and the plurality of the compounds are stacked so that x decreases in the direction from the first electrode toward the second electrode: 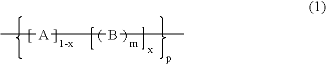
wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B is a hole-transporting repeating unit selected from the group consisting of a substituted or unsubstituted arylene group of C₆-C₃₀, a substituted or unsubstituted heteroarylene group of C₂-C₃₀, a group represented by 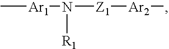
a group represented by 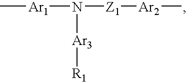
a group represented by 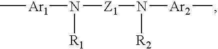
and a group represented by 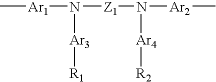
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
m is 1 or 2;
x is a real number of 0.01 to 0.99; and
p is the degree of polymerization and a real number of 10 to 2,000.

7. The organic light-emitting device of claim 6, wherein the light-emitting repeating unit represented by A and the hole-transporting repeating unit represented by B are each independently substituted by at least one selected from the group consisting of a hydroxyl group, a cyano group, a halogen atom, an alkyl group of C₁-C₃₀ which is unsubstituted or substituted by a hydroxyl group, a cyano group, or a halogen atom, a cycloalkyl group of C₃-C₃₀ which is unsubstituted or substituted by a hydroxyl group, a cyano group, or a halogen atom, an alkoxy group of C₁-C₃₀ which is unsubstituted or substituted by a hydroxyl group, a cyano group, or a halogen atom, an aryl group of C₆-C₃₀ which is unsubstituted or substituted by a hydroxyl group, a cyano group, or a halogen atom, an arylalkyl group of C₆-C₃₀ which is unsubstituted or substituted by a hydroxyl group, a cyano group, or a halogen atom, a heteroaryl group of C₂-C₃₀ which is unsubstituted or substituted by a hydroxyl group, a cyano group, or a halogen atom, a heterocyclic group of C₂-C₃₀ which is unsubstituted or substituted by a hydroxyl group, a cyano group, or a halogen atom, and a group represented by —N(R′)(R″) where R′ and R″ are each independently selected from the group consisting of hydrogen, an alkyl group of C₁-C₃₀, an aryl group of C₆-C₃₀, and a heteroaryl group of C₂-C₃₀.

8. The organic light-emitting device of claim 6, wherein the light-emitting repeating unit represented by A is selected from the group consisting of 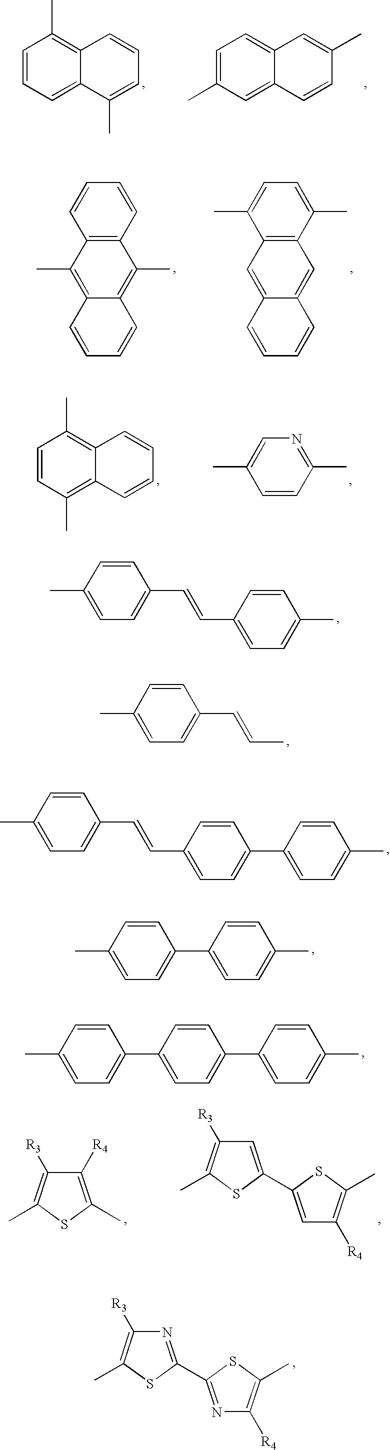 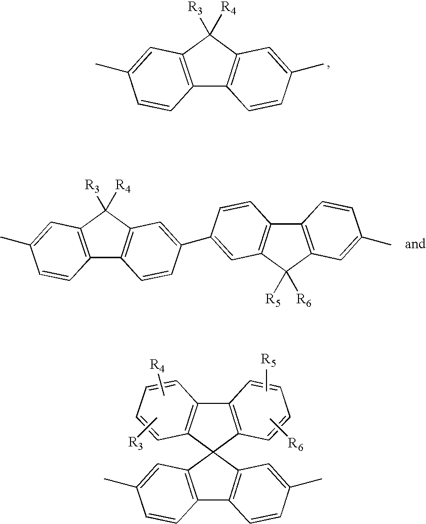
where R₃, R₄, R₅ and R₆ are each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

9. The organic light-emitting device of claim 6, wherein the light-emitting repeating unit represented by A is 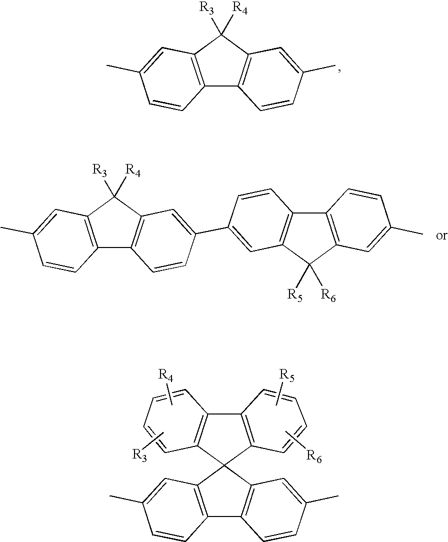
where R₃, R₄, R₅ and R₆ are each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

10. The organic light-emitting device of claim 6, wherein the hole-transporting repeating unit represented by B is selected from the group consisting of 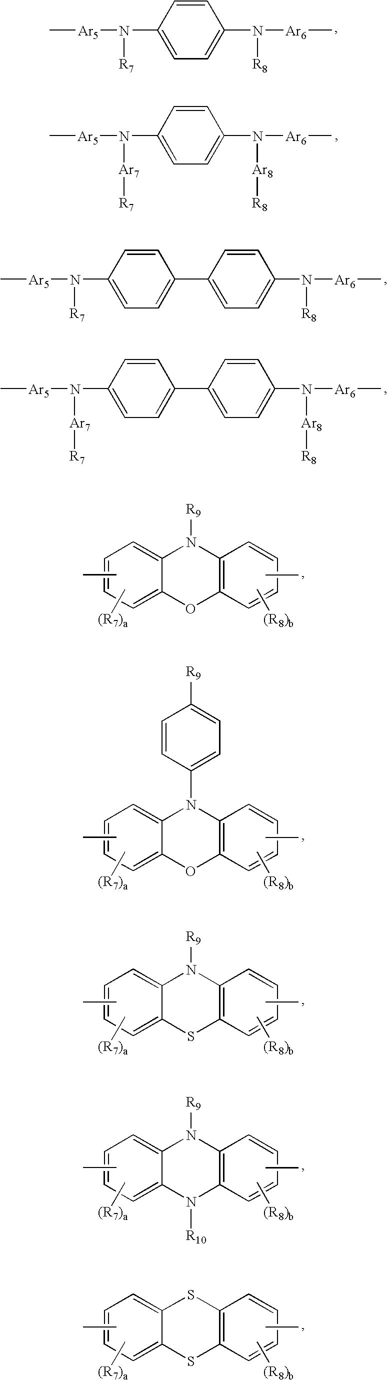 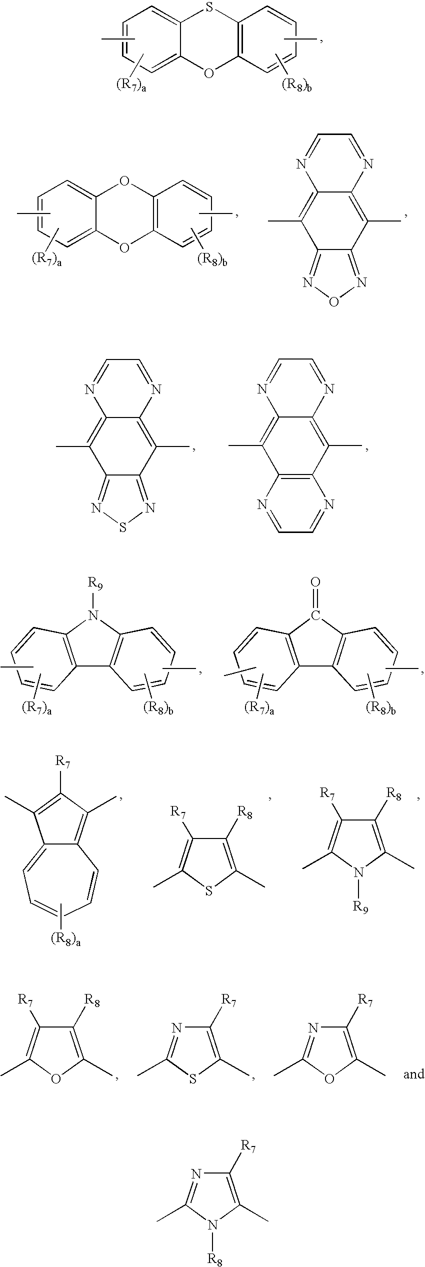
where Ar₅, Ar₆, Ar₇ and Ar₈ are each independently an arylene group of C₆-C₃₀ or a heteroarylene group of C₅-C₃₀, R₇, R₈, R₉ and R₁₀ are each independently hydrogen, an alkyl group of C₁-C₁₂, an alkoxy group of C₁-C₁₂, an aryl group of C₆-C₃₀, or a heteroaryl group of C₆-C₃₀, and a and b are each independently 1, 2, 3, 4 or 5.

11. The organic light-emitting device of claim 6, wherein the hole-transporting repeating unit represented by B is 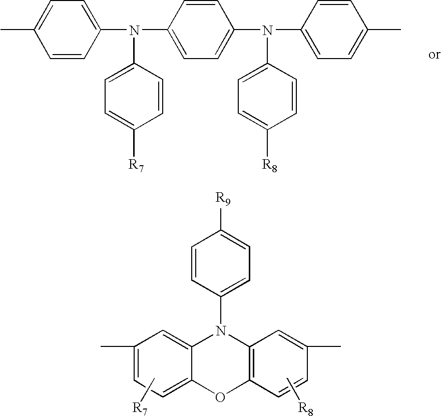
wherein R₇, R₈ and R₉ are hydrogen, an alkyl group of C₁-C₁₂, an alkoxy group of C₁-C₁₂, an aryl group of C₆-C₃₀, or a heteroaryl group of C₆-C₃₀.

12. The organic light-emitting device of claim 6, wherein the plurality of compounds comprise a compound represented by Formula 1a and a compound represented by Formula 1b, x₁ of the compound of Formula 1a and x₂ of the compound of Formula 1b satisfy the requirement of x₁>x₂, and the compound of Formula 1a and the compound of Formula 1b are sequentially stacked from the first electrode: 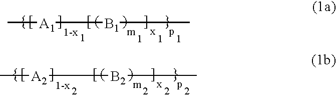
wherein A₁ and A₂ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B₁ and B₂ are each independently a hole-transporting repeating unit selected from the group consisting of a substituted or unsubstituted arylene group of C₆-C₃₀, a substituted or unsubstituted heteroarylene group of C₂-C₃₀, a group represented by 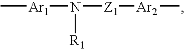
a group represented by 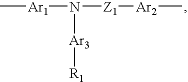
a group represented by 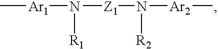
and a group represented by 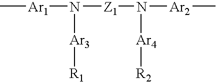
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
m₁ and m₂ are each independently 1 or 2;
x₁ and x₂ are each independently a real number of 0.01 to 0.99; and
p₁ and P₂ are the degree of polymerization and each independently a real number of 10 to 2,000.

13. The organic light-emitting device of claim 6, wherein the plurality of compounds comprise a compound represented by Formula 1a, a compound represented by Formula 1b, and a compound represented by Formula 1c, x₁ of the compound of Formula 1a, x₂ of the compound of Formula 1b, and x₃ of the compound of Formula 1c satisfy the requirement of x₁>x₂>x₃, and the compound of Formula 1a, the compound of Formula 1b, and the compound of Formula 1c are sequentially stacked from the first electrode: 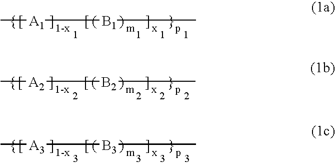
wherein A₁, A₂ and A₃ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B₁, B₂ and B₃ are each independently a hole-transporting repeating unit selected from the group consisting of a substituted or unsubstituted arylene group of C₆-C₃₀, a substituted or unsubstituted heteroarylene group of C₂-C₃₀, a group represented by 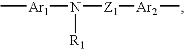
a group represented by 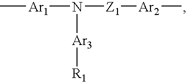
a group represented by 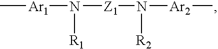
and a group represented by 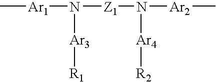
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
m₁, m₂ and m₃ are each independently 1 or 2;
x₁, x₂ and x₃ are each independently a real number of 0.01 to 0.99; and
p₁, p₂ and p₃ are the degree of polymerization and each independently a real number of 10 to 2,000.

14. The organic light-emitting device of claim 12, wherein x₁ is 0.5 and x₂ is 0.1.

15. The organic light-emitting device of claim 12, wherein x₁ is 0.9, x₂ is 0.5, and x₃ is 0.1.

16. The organic light-emitting device of claim 5, wherein the organic layer further comprises at least one selected from the group consisting of a hole injection layer, a hole transport layer, a hole blocking layer, an electron blocking layer, an electron transport layer, and an electron injection layer.

17. An organic light-emitting device, comprising:
a first electrode;
a second electrode; and
an organic layer interposed between the first electrode and the second electrode, the organic layer comprising at least a light-emitting layer, the light-emitting layer comprising a plurality of compounds each of which has a light-emitting repeating unit and an electron-transporting repeating unit, the plurality of compounds being different in the molar ratio of the light-emitting repeating unit and the electron-transporting repeating unit, the molar ratio of the electron-transporting repeating unit in the light-emitting layer increasing in the direction from the first electrode toward the second electrode.

18. The organic light-emitting device of claim 17, wherein the plurality of compounds are represented by Formula 2, and the plurality of the compounds are stacked so that y increases in the direction from the first electrode toward the second electrode: 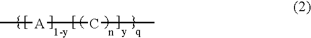
wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
C is an electron-transporting repeating unit selected from the group consisting of a substituted or unsubstituted arylene group of C₆-C₃₀ and a substituted or unsubstituted heteroarylene group of C₂-C₃₀;
n is 1 or 2;
y is a real number of 0.01 to 0.99; and
q is the degree of polymerization and a real number of 10 to 2,000.

19. The organic light-emitting device of claim 18, wherein the light-emitting repeating unit represented by A and the electron-transporting repeating unit represented by C are each independently substituted by at least one selected from the group consisting of a hydroxyl group, a cyano group, a halogen atom, an alkyl group of C₁-C₃₀ which is unsubstituted or substituted by a hydroxyl group, a cyano group, or a halogen atom, a cycloalkyl group of C₃-C₃₀ which is unsubstituted or substituted by a hydroxyl group, a cyano group, or a halogen atom, an alkoxy group of C₁-C₃₀ which is unsubstituted or substituted by a hydroxyl group, a cyano group, or a halogen atom, an aryl group of C₆-C₃₀ which is unsubstituted or substituted by a hydroxyl group, a cyano group, or a halogen atom, an arylalkyl group of C₆-C₃₀ which is unsubstituted or substituted by a hydroxyl group, a cyano group, or a halogen atom, a heteroaryl group of C₂-C₃₀ which is unsubstituted or substituted by a hydroxyl group, a cyano group, or a halogen atom, a heterocyclic group of C₂-C₃₀ which is unsubstituted or substituted by a hydroxyl group, a cyano group, or a halogen atom, and a group represented by —N(R′)(R″) where R′ and R″ are each independently selected from the group consisting of hydrogen, an alkyl group of C₁-C₃₀, an aryl group of C₆-C₃₀, and a heteroaryl group of C₂-C₃₀.

20. The organic light-emitting device of claim 18, wherein the light-emitting repeating unit represented by A is selected from the group consisting of 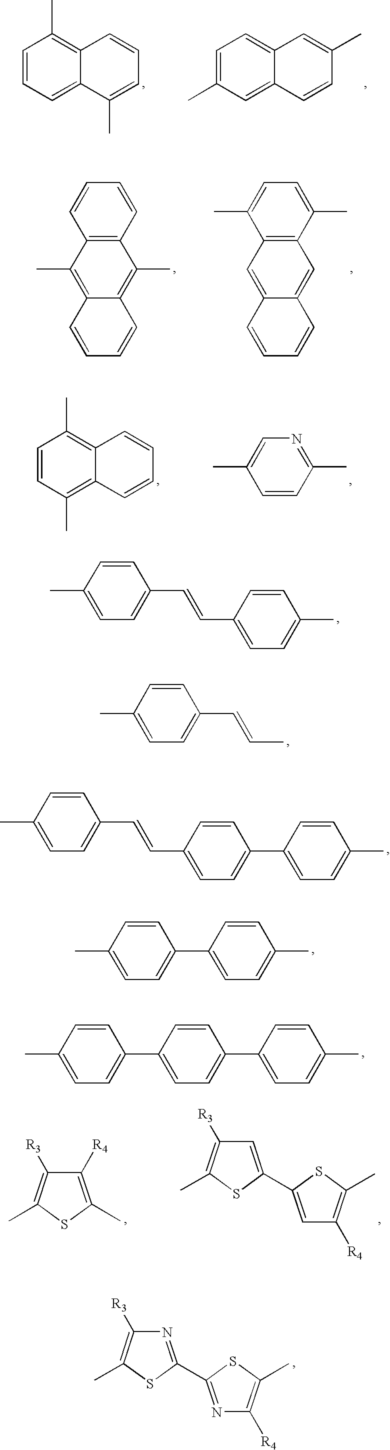 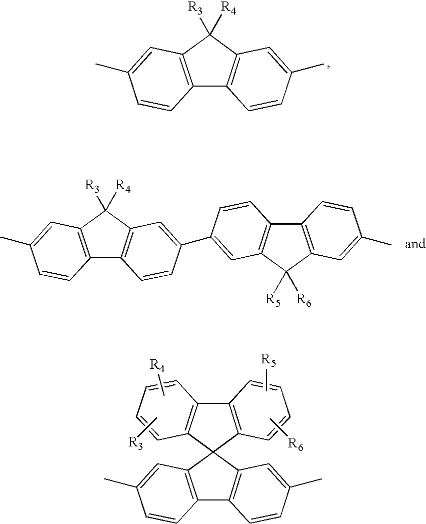
where R₃, R₄, R₅ and R₆ are each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

21. The organic light-emitting device of claim 18, wherein the light-emitting repeating unit represented by A is 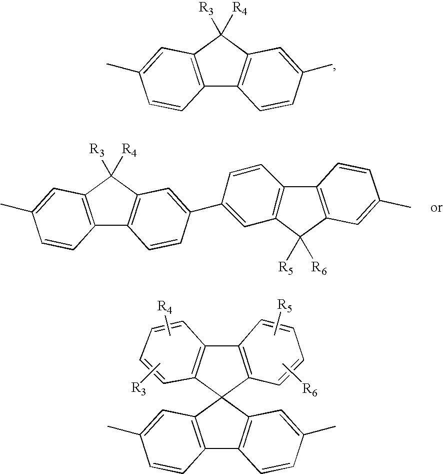
where R₃, R₄, R₅ and R₆ are each independently hydrogen, an alkyl group of C₁-C₁₂, an alkoxy group of C₁-C₁₂, or —N(R′)(R″) where R′ and R″ are each independently hydrogen, an alkyl group of C₁-C₁₂, an aryl group of C₆-C₃₀, or a heteroaryl group of C₂-C₃₀.

22. The organic light-emitting device of claim 18, wherein the electron-transporting repeating unit represented by C is selected from the group consisting of 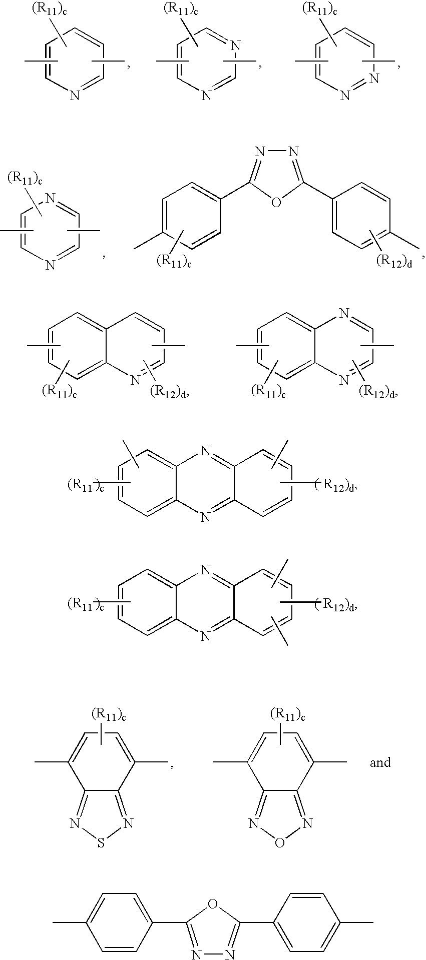
wherein R₁₁ and R₁₂ are each independently hydrogen, an alkyl group of C₁-C₁₂, an alkoxy group of C₁-C₁₂, an aryl group of C₆-C₃₀, or a heteroaryl group of C₆-C₃₀; and
c and d are each independently 1, 2, 3 or 4.

23. The organic light-emitting device of claim 18, wherein the electron-transporting repeating unit represented by C is 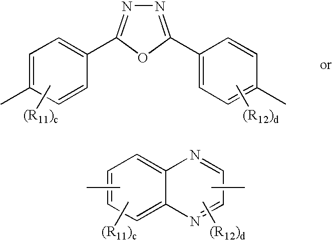
wherein R₁₁ and R₁₂ are hydrogen, an alkyl group of C₁-C₁₂, an alkoxy group of C₁-C₁₂, an aryl group of C₆-C₃₀, or a heteroaryl group of C₆-C₃₀; and c and d are each independently 1, 2, 3, or 4.

24. The organic light-emitting device of claim 18, wherein the plurality of compounds comprise a compound represented by Formula 2a and a compound represented by Formula 2b, y₁ of the compound of Formula 2a and y₂ of the compound of Formula 2b satisfy the requirement of y₁<y₂, and the compound of Formula 2a and the compound of Formula 2b are sequentially stacked from the first electrode: 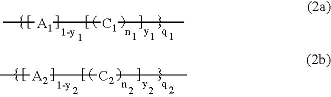
wherein A₁ and A₂ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
C₁ and C₂ are each independently an electron-transporting repeating unit selected from the group consisting of a substituted or unsubstituted arylene group of C₆-C₃₀ and a substituted or unsubstituted heteroarylene group of C₂-C₃₀;
n₁ and n₂ are each independently 1 or 2;
y₁ and y₂ are each independently a real number of 0.01 to 0.99; and
q₁ and q₂ are the degree of polymerization, and each independently a real number of 10 to 2,000.

25. The organic light-emitting device of claim 18, wherein the plurality of compounds comprise a compound represented by Formula 2a, a compound represented by Formula 2b, and a compound represented by Formula 2c, y₁ of the compound of Formula 2a, y₂ of the compound of Formula 2b, and y₃ of the compound of Formula 2c satisfy the requirement of y₁<y₂<y₃, and the compound of Formula 2a, the compound of Formula 2b, and the compound of Formula 2c are sequentially stacked from the first electrode: 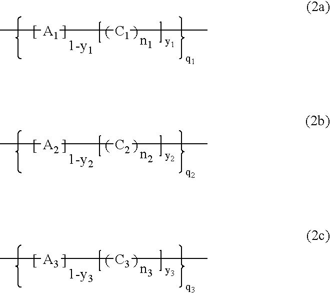
wherein A₁, A₂ and A₃ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₄-C₃₀;
C₁, C₂ and C₃ are each independently an electron-transporting repeating unit selected from the group consisting of a substituted or unsubstituted arylene group of C₆-C₃₀ and a substituted or unsubstituted heteroarylene group of C₂-C₃₀;
n₁, n₂ and n₃ are each independently 1 or 2;
y₁, y₂ and y₃ are each independently a real number of 0.01 to 0.99; and
q₁, q₂ and q₃ are the degree of polymerization, and each independently a real number of 10 to 2,000.

26. The organic light-emitting device of claim 24, wherein y₁ is 0.1 and y₂ is 0.5.

27. The organic light-emitting device of claim 25, wherein y₁ is 0.1, y₂ is 0.5, and y₃ is 0.9.

28. An organic light-emitting device, comprising:
a first electrode;
a second electrode; and
an organic layer interposed between the first electrode and the second electrode, the organic layer comprising at least a light-emitting layer, the light-emitting layer comprising a plurality of compounds each of which has a light-emitting repeating unit, a hole-transporting repeating unit, and an electron-transporting repeating unit, the plurality of compounds being different in the molar ratio of the light-emitting repeating unit, the hole-transporting repeating unit, and the electron-transporting repeating unit, the molar ratio of the hole-transporting repeating unit in the light-emitting layer decreasing and the molar ratio of the electron-transporting repeating unit in the light-emitting layer increasing in the direction from the first electrode toward the second electrode.

29. The organic light-emitting device of claim 28, wherein the plurality of compounds comprise a plurality of compounds represented by Formula 3, and the plurality of the compounds are stacked so that x decreases and y increases in the direction from the first electrode toward the second electrode: 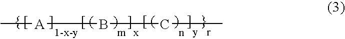
wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B is a hole-transporting repeating unit selected from the group consisting of a substituted or unsubstituted arylene group of C₆-C₃₀, a substituted or unsubstituted heteroarylene group of C₂-C₃₀, a group represented by 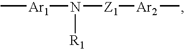
a group represented by 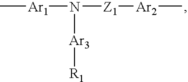
a group represented by 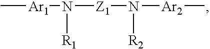
and a group represented by 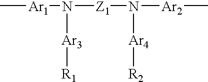
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
C is an electron-transporting repeating unit selected from the group consisting of a substituted or unsubstituted arylene group of C₆-C₃₀ and a substituted or unsubstituted heteroarylene group of C₂-C₃₀;
m and n are each independently 1 or 2;
x and y are each independently a real number of 0.01 to 0.99; and
r is the degree of polymerization and a real number of 10 to 2,000.

30. The organic light-emitting device of claim 29, wherein the plurality of compounds comprise a compound represented by Formula 3a and a compound represented by Formula 3b, x₁ and y₁ of the compound of Formula 3a and x₂ and y₂ of the compound of Formula 3b satisfy the requirements of x₁>x₂ and y₁<y₂, and the compound of Formula 3a and the compound of Formula 3b are sequentially stacked from the first electrode: 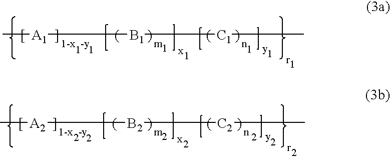
wherein A₁ and A₂ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B₁ and B₂ are each independently a hole-transporting repeating unit selected from the group consisting of a substituted or unsubstituted arylene group of C₆-C₃₀, a substituted or unsubstituted heteroarylene group of C₂-C₃₀, a group represented by 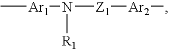
a group represented by 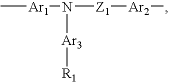
a group represented by 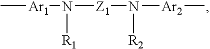
and a group represented by 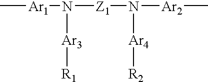
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
C₁ and C₂ are each independently an electron-transporting repeating unit selected from the group consisting of a substituted or unsubstituted arylene group of C₆-C₃₀ and a substituted or unsubstituted heteroarylene group of C₂-C₃₀;
m₁, m₂, n₁ and n₂ are each independently 1 or 2;
x₁, x₂, y₁ and y₂ are each independently a real number of 0.01 to 0.99; and
r₁ and r₂ are the degree of polymerization, and each independently a real number of 10 to 2,000.

31. The organic light-emitting device of claim 29, wherein the plurality of compounds comprise a compound represented by Formula 3a, a compound represented by Formula 3b, and the compound represented by Formula 3c, x₁ and y₁ of the compound of Formula 3a, x₂ and y₂ of the compound of Formula 3b, and x₃ and y₃ of the compound of Formula 3c satisfy the requirements of x₁>x₂>x₃ and y₁<y₂<y₃, and the compound of Formula 3a, the compound of Formula 3b, and the compound of Formula 3c are sequentially stacked from the first electrode: 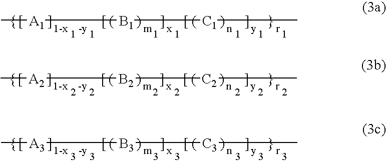
wherein A₁, A₂ and A₃ are each independently a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B₁, B₂ and B₃ are each independently a hole-transporting repeating unit selected from the group consisting of a substituted or unsubstituted arylene group of C₆-C₃₀, a substituted or unsubstituted heteroarylene group of C₂-C₃₀, a group represented by 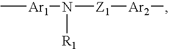
a group represented by 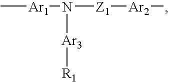
a group represented by 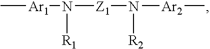
and a group represented by 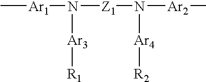
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
C₁, C₂ and C₃ are each independently an electron-transporting repeating unit selected from the group consisting of a substituted or unsubstituted arylene group of C₆-C₃₀ and a substituted or unsubstituted heteroarylene group of C₂-C₃₀;
m₁, m₂, and m₃ are each independently 1 or 2;
n₁, n₂ and n₃ are each independently 1 or 2;
x₁, x₂, x₃ are each independently a real number of 0.01 to 0.99;
y₁, y₂ and y₃ are each independently a real number of 0.01 to 0.99; and
r₁, r₂ and r₃ are the degree of polymerization, and each independently a real number of 10 to 2,000.

32. A method of manufacturing an organic light-emitting device, the method comprising:
preparing a substrate having a first electrode;
forming an organic layer on the first electrode; and
forming a second electrode on the organic layer, the organic layer comprising at least a light-emitting layer made of a plurality of compounds each of which comprises a light-emitting repeating unit and a hole-transporting repeating unit, the molar ratio of the hole-transporting repeating unit decreasing in the direction from the first electrode toward the second electrode.

33. The method of claim 32, wherein the plurality of compounds are represented by Formula 1, and the plurality of the compounds are stacked so that x decreases in the direction from the first electrode toward the second electrode: 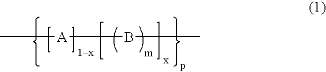
wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B is a hole-transporting repeating unit selected from the group consisting of a substituted or unsubstituted arylene group of C₆-C₃₀, a substituted or unsubstituted heteroarylene group of C₂-C₃₀, a group represented by 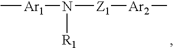
a group represented by 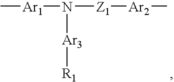
a group represented by 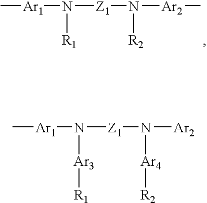
and a group represented by
where Z₁ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
m is 1 or 2;
x is a real number of 0.01 to 0.99; and
p is the degree of polymerization and a real number of 10 to 2,000.

34. A method of manufacturing an organic light-emitting device, the method comprising:
preparing a substrate having a first electrode;
forming an organic layer on the first electrode; and
forming a second electrode on the organic layer, the organic layer comprising at least a light-emitting layer made of a plurality of compounds each of which comprises a light-emitting repeating unit and an electron-transporting repeating unit, the molar ratio of the electron-transporting repeating unit increasing in the direction from the first electrode toward the second electrode.

35. The method of claim 34, wherein the plurality of compounds are represented by Formula 2, and the plurality of the compounds are stacked so that y increases in the direction from the first electrode toward the second electrode: 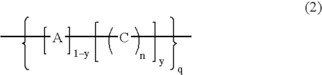
wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
C is an electron-transporting repeating unit selected from the group consisting of a substituted or unsubstituted arylene group of C₆-C₃₀ and a substituted or unsubstituted heteroarylene group of C₂-C₃₀;
n is 1 or 2;
y is a real number of 0.01 to 0.99; and
q is the degree of polymerization and a real number of 10 to 2,000.

36. A method of manufacturing an organic light-emitting device, the method comprising:
preparing a substrate having a first electrode;
forming an organic layer on the first electrode; and
forming a second electrode on the organic layer, the organic layer comprising at least a light-emitting layer made of a plurality of compounds each of which comprises a light-emitting repeating unit, a hole-transporting repeating unit, and an electron-transporting repeating unit, the molar ratio of the hole-transporting repeating unit decreasing and the molar ratio of the electron-transporting repeating unit increasing in the direction from the first electrode toward the second electrode.

37. The method of claim 36, wherein the plurality of compounds are represented by Formula 3, and the plurality of the compounds are stacked so that x decreases and y increases in the direction from the first electrode toward the second electrode: 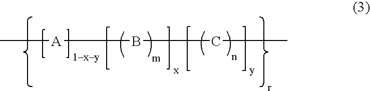
wherein A is a light-emitting repeating unit selected from the group consisting of a substituted or unsubstituted arylene group of C₆-C₃₀, a substituted or unsubstituted vinylenearylene group of C₆-C₃₀, and a substituted or unsubstituted heteroarylene group of C₂-C₃₀;
B is a hole-transporting repeating unit selected from the group consisting of a substituted or unsubstituted arylene group of C₆-C₃₀, a substituted or unsubstituted heteroarylene group of C₂-C₃₀, a group represented by 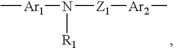
a group represented by 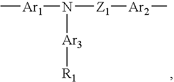
a group represented by 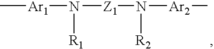
and a group represented by 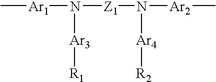
where Z₂ is a bond, an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀;
Ar₁, Ar₂, Ar₃ and Ar₄ are each independently an arylene group of C₆-C₃₀ which is unsubstituted or substituted by at least one selected from the group consisting of a hydroxyl group, a cyano group, a halogen atom, an alkyl group of C₁-C₃₀, and an alkoxy group of C₁-C₃₀, or a heteroarylene group of C₂-C₃₀ which is unsubstituted or substituted by at least one selected from the group consisting of a hydroxyl group, a cyano group, a halogen atom, an alkyl group of C₁-C₃₀, and an alkoxy group of C₁-C₃₀; and
R₁ and R₂ are an alkyl group of C₁-C₃₀ which is unsubstituted or substituted by at least one selected from the group consisting of a hydroxyl group, a cyano group, and a halogen atom, an alkoxy group of C₁-C₃₀ which is unsubstituted or substituted by at least one selected from the group consisting of a hydroxyl group, a cyano group, and a halogen atom, an aryl group of C₆-C₃₀ which is unsubstituted or substituted by at least one selected from the group consisting of a hydroxyl group, a cyano group, and a halogen atom, or a heteroaryl group of C₂-C₃₀ which is unsubstituted or substituted by at least one selected from the group consisting of a hydroxyl group, a cyano group, and a halogen atom;
C is an electron-transporting repeating unit selected from the group consisting of a substituted or unsubstituted arylene group of C₆-C₃₀ and a substituted or unsubstituted heteroarylene group of C₂-C₃₀;
m and n are each independently 1 or 2;
x and y are each independently a real number of 0.01 to 0.99; and
r is the degree of polymerization and a real number of 10 to 2,000.
